(19) United States
(12) Patent Application Publication
(10) Pub. No.: US 2024/0111926 A1
(43) Pub. Date: Apr. 4, 2024

(54) REPROGRAMMABLE SYSTEMS AND METHODS FOR CONTROLLING THE SAME

(71) Applicant: University of Washington, Seattle, WA (US)

(72) Inventors: Jeffrey Lipton, Seattle, WA (US); Sawyer Thomas, Seattle, WA (US)

(21) Appl. No.: 18/275,985

(22) PCT Filed: Feb. 7, 2022
(86) PCT No.: PCT/US2022/015526

§ 371 Date: Aug. 4, 2023

Related U.S. Application Data
(60) Provisional application No. 63/147,001, filed on Feb. 8, 2021.

(51) Int. Cl. G06F 30/23; G06F 30/17

(52) U.S. Cl. CPC G06F 30/23; G06F 30/17

(57) ABSTRACT

Described herein are reprogrammable systems and methods for controlling the same. The reprogrammable system comprises a first side configured to be reprogrammable in at least a first direction. The first side is formed by a reprogrammable structure having one or more layers stacked in a second direction. An individual layer of the one or more layers has repeating unit cells. A first unit cell of the repeating unit cells has elements. The elements are connected by connecting joints. A first unit cell of the repeating unit cells shares at least one element and/or at least one connecting joint with a second unit cell of the repeating unit cells.

### CROSS-REFERENCE TO RELATED APPLICATION

This application claims the priority of U.S. Provisional Application No. 63/147,001, which was filed on Feb. 8, 2021 and is incorporated by reference herein in its entirety.

### FIELD

This disclosure relates to systems and methods for improving reprogrammable metamaterial, and more specifically relates to reprogrammable systems and methods for controlling the same.

### BACKGROUND

In the natural world, rapid shifts in texture allow animals such as frogs, cuttlefish, and octopi to blend into their surroundings [1]-[3], and in our own fingertips, the wrinkling of the skin improves our ability to grip objects underwater [4]. The ability to change a surface's profile allows biological systems to effectively manipulate and blend into their surroundings.

Despite the utility found by nature, the ability to produce varied and passively stable surface changes in mechanical devices on demand has eluded researchers. Current morphing surfaces technologies rely either on individual actuators to drive and maintain system states, making them large, inefficient, and difficult to build [5]-[8], or they must be programmed at construction, limiting the range of accessible states for a single structure [9]-[17]. Current mechanical metamaterials are generally designed for a single specific task. For every additional adjustment, they need to be redesigned and refabricated.

### SUMMARY

To address the above challenges, this disclosure provides reprogrammable systems and methods for controlling the same. The reprogrammable system can generate arbitrary surface profiles and be rewritten after fabrication. The reprogrammable system has a transition state where small inputs can cause the reprogrammable system to have significantly different responses to a global force. Both the global and local Poisson's ratio of the reprogrammable system can be controlled. The reprogrammable system can be used to present edge profiles, 2-Dimensional (2D) information, 3-Dimensional (3D) surfaces, and the like. The reprogrammable system can be rapidly reprogrammed to transform into a wide range of desired shapes and profiles.

An aspect of this disclosure provides a reprogrammable system. The reprogrammable system comprises a first side configured to be reprogrammable in at least a first direction. The first side is formed by a reprogrammable structure having one or more layers stacked in a second direction. An individual layer of the one or more layers has repeating unit cells. A first unit cell of the repeating unit cells has elements. The elements are connected by connecting joints. A first unit cell of the repeating unit cells shares at least one element and/or at least one connecting joint with a second unit cell of the repeating unit cells.

Another aspect of this disclosure provides a method for controlling the reprogrammable system as described above. The method comprises the following operations. The reprogrammable structure is encoded by calculating a system matrix based on a desired profile to be displayed. The system matrix has joint values for the connecting joints. An individual joint value defines an angle between two elements connected by an individual connecting joint. The reprogrammable structure is encoded by biasing the connecting joints based on the system matrix. The desired profile is expressed via the first side in the first direction by applying a global force to the reprogrammable structure.

Yet another aspect of this disclosure provides a computer-readable storage medium storing computer-readable instructions executable by one or more processors, that when executed by the one or more processors, causes the one or more processors to perform the following acts. The reprogrammable structure is encoded by calculating a system matrix based on a desired profile to be displayed. The system matrix has joint values for the connecting joints. An individual joint value defines an angle between two elements connected by an individual connecting joint. The reprogrammable structure is encoded by biasing the connecting joints based on the system matrix. The desired profile is expressed via the first side in the first direction by applying a global force to the reprogrammable structure.

Small nudges can shift the local and/or the global Poisson's ratio of the reprogrammable system, causing the first side of the reprogrammable system take on different shapes under a global compressive force. By actively biasing/actuating the connecting joints, the reprogrammable system can produce a reprogrammable first side that does not require inputs to maintain shape and can display arbitrary 2D information and/or take on complex 3D shapes. Such a reprogrammable system opens new opportunities in micro devices, tactile/haptic displays such as braille displays, manufacturing, and robotic systems.

### BRIEF DESCRIPTION OF THE DRAWINGS

Some of the drawings submitted herein may be better understood in color. Applicant considers the color versions of the drawings as part of the original submission and reserves the right to present color images of the drawings in later proceedings.

In the drawing, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted. In particular, some of the figures may depict components as a certain size or shape, while other figures may depict the same components on a larger scale or differently shaped for the sake of clarity.

FIG. 1A illustrates a schematic diagram of an example reprogrammable system according to implementations of this disclosure.

FIG. 1B illustrates various views of the reprogrammable system according to implementations of this disclosure.

FIG. 1C illustrates a schematic diagram of the reprogrammable structure of the reprogrammable system according to implementations of this disclosure.

FIG. 1D illustrates a schematic diagram of an example individual layer (such as the first layer) according to implementations of this disclosure.

FIG. 1E illustrates various views of an example individual unit cell (such as the first unit cell) according to implementations of this disclosure.

FIG. 1F illustrates an example individual layer (such as the first layer) where the connecting joints are biased manually according to implementations of this disclosure.

FIG. 1G illustrates various views of the biasing block according to implementations of this disclosure.

FIG. 1H illustrates an image of a part of an example individual layer (such as the first layer) where the connecting joints are biased electrically/robotically according to implementations of this disclosure.

FIG. 1I illustrates an image of the reprogrammable system (without caps) in an extended state according to implementations of this disclosure.

FIG. 1J illustrates an image of the reprogrammable system (without caps) in an extended state according to implementations of this disclosure.

FIG. 2A illustrates a flowchart of an example process for controlling the reprogrammable system according to implementations of this disclosure.

FIG. 2B illustrates a flowchart of an example process for controlling the reprogrammable system according to implementations of this disclosure.

FIG. 3 illustrates induced global changes in Poisson's ratio of an example auxetic structure (lattice) according to implementations of this disclosure.

FIG. 4 illustrates experimental data showing the relationship between axial and lateral deformation and the calculation of the average Poisson's ratio.

FIG. 5 illustrates profile generation in biased metamaterial (auxetic structure) according to implementations of this disclosure.

FIG. 6A illustrates reprogrammable height field according to implementations of this disclosure.

FIG. 6B illustrates a binary surface reprogramming according to implementations of this disclosure.

FIG. 7 illustrates a graph showing the combined space for a single layer of an auxetic structure.

FIG. 8A illustrates a first type of auxetic structure with double arrowhead unit cells according to implementations of this disclosure.

FIG. 8B illustrates a second type of auxetic structure with reentrant honeycomb unit cells according to implementations of this disclosure.

FIG. 8C illustrates a third type of example auxetic structure with rotating square unit cells according to implementations of this disclosure.

FIG. 9 shows images of the auxetic structure with reentrant honeycomb unit cells and the auxetic structure with double arrowhead unit cells according to implementations of this disclosure.

FIG. 10 illustrates Finite Element Analysis (FEA) simulations to compare buckling of the auxetic structure with two bar elements versus the auxetic structure with single bar elements under predefined axial deformation and similar joint loading conditions.

FIG. 11A illustrates design and application scenarios and of an example biasing block according to implementations of this disclosure.

FIG. 11B illustrates different views of an alternate biasing block according to implementations of this disclosure.

FIG. 12 illustrates the design and the fabrication of electrically reprogrammable planner auxetic structures.

FIG. 13 illustrates scenarios of robotically switching the electrically reprogrammable planner auxetic structures.

FIG. 14 illustrates a 3D reprogrammable system according to implementations of this disclosure.

FIG. 15 illustrates binary surface reprogramming according to implementations of this disclosure.

FIG. 16A illustrates a single compliant 4-bar unit cell and 3D printed blockers for constraining the deformation of the cell.

FIG. 16B illustrates reprogrammable star graph configuration.

FIG. 16C illustrates that a single 2×2 linkage unit cell can be reprogrammed to 4 cell types (6 including mirrors), each with different mechanical properties.

FIG. 16D illustrates that encoding different unit cells throughout a structure enables complex deformations of a 3D printed lattice.

FIG. 17 illustrates complex shape generation according to implementations of this disclosure.

FIG. 18 illustrates binary information representation according to implementations of this disclosure.

FIG. 19 illustrates 3D surface expression according to implementations of this disclosure.

FIG. 20A illustrates an example of valid structure combination check according to implementations of this disclosure.

FIG. 20B illustrates an example of invalid structure combination check according to implementations of this disclosure.

FIG. 21A, FIG. 21B, and FIG. 21C illustrate a combination space for total joint combinations and valid joint combinations.

FIG. 22 illustrates the FEA simulation that validated the design strategy for creating predictably compressible lattice structures.

FIG. 23 illustrates function approximation and lattice representation according to implementations of this disclosure.

FIG. 24 illustrates transition modes for honeycomb unit cells according to implementations of this disclosure.

FIG. 25 illustrates robotically switching lattice according to implementations of this disclosure.

FIG. 26A illustrates various perspective views of the reprogrammable system according to implementations of this disclosure.

FIG. 26B illustrates various side views of the reprogrammable system according to implementations of this disclosure.

FIG. 27 illustrates various views of an example individual unit cell in the reprogrammable system according to implementations of this disclosure.

FIG. 28 illustrates various views of an example individual unit cell with an example collinear mechanism according to implementations of this disclosure.

FIG. 29 illustrates various views of an example individual unit cell with another example collinear mechanism according to implementations of this disclosure.

### DETAILED DESCRIPTION

The Detailed Description is set forth with reference to the accompanying figures. Throughout this disclosure, definitions of terms are as follows.

Auxetic structure: structures consist of a number of unit cells arranged in such a way that the overall structure expands when stretched and contracts when compressed. The auxetic structure is also referred to as auxetic lattice or auxetic material.

Poisson's ratio: a measure of the Poisson effect, the deformation (expansion or contraction) of material in directions perpendicular to the specific direction of loading.

The elements of the unit cell may also be referred to as linkages, links, bars, beams, and the like. The unit cells may also be referred to as cells, lattice cells, and the like. The auxetic structures may also be referred to as structures, lattices, lattice structures, and the like. The biasing blocks may also be referred to as blockers, blocking elements, and the like.

Definitions and explanations used in this disclosure are meant and intended to be controlling in any future construction. Terms that are not defined otherwise should be taken as their plain meanings to those of ordinary skill in the art. In case there is any ambiguity, the definition should be taken from a dictionary known to those of ordinary skill in the art such as the Webster's Dictionary, the Oxford Dictionary, and the like.

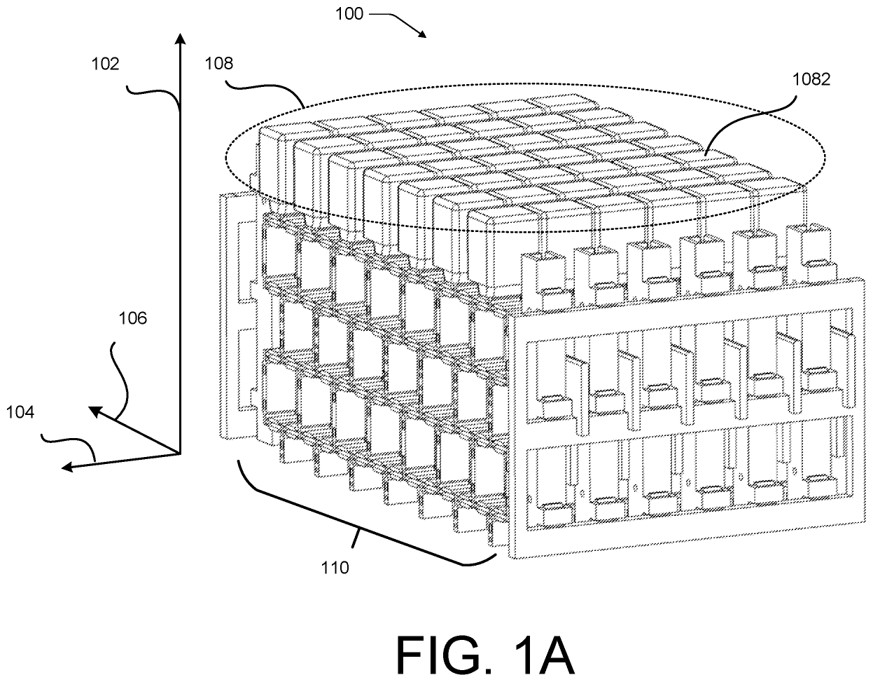

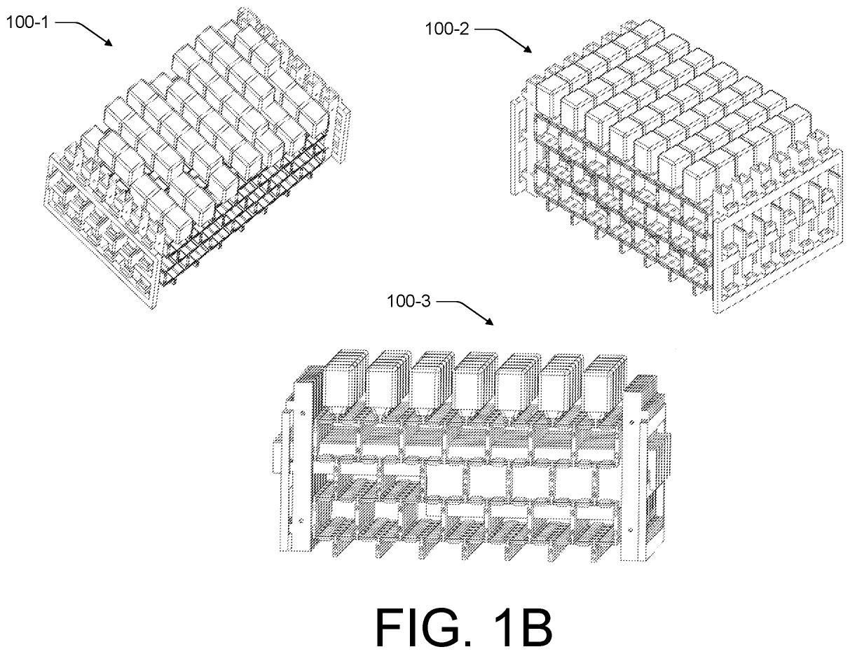

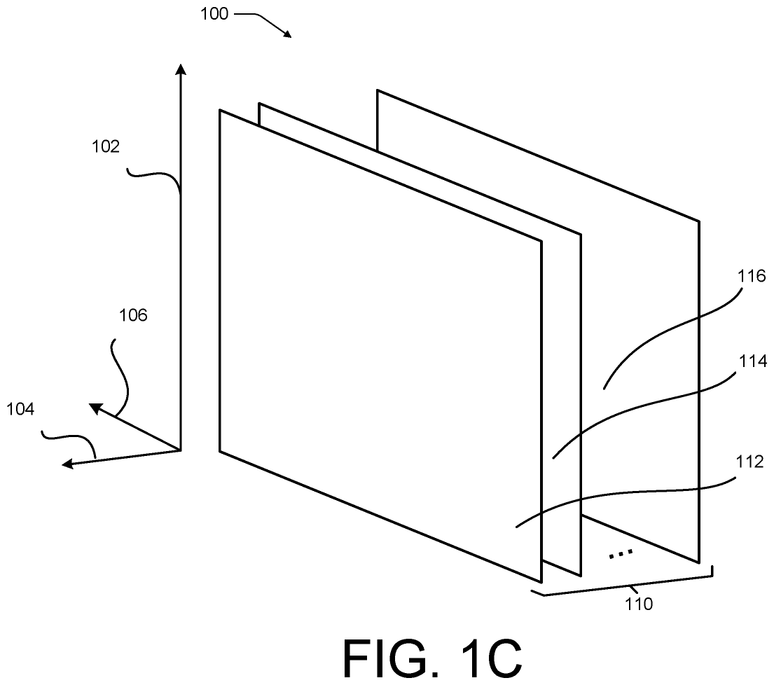

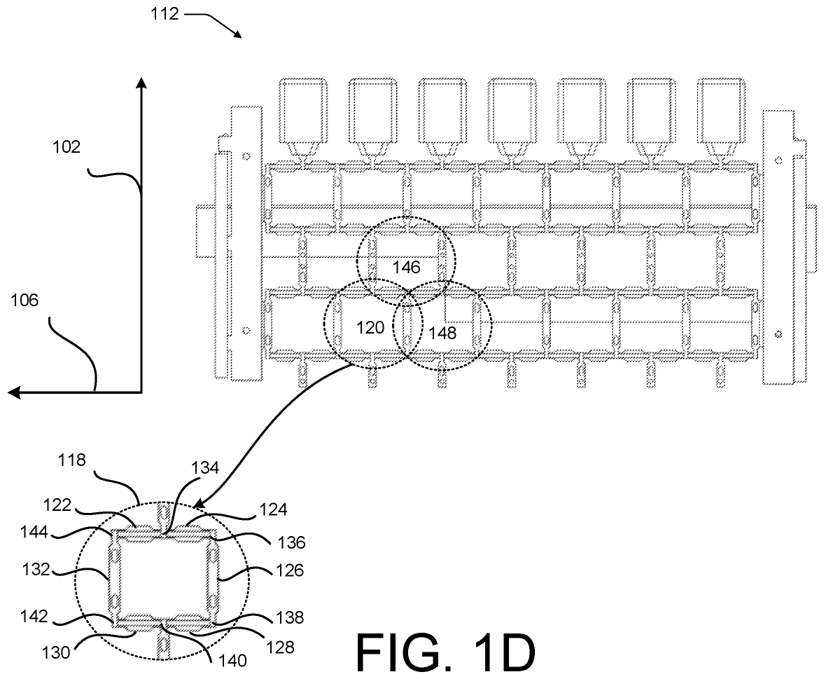

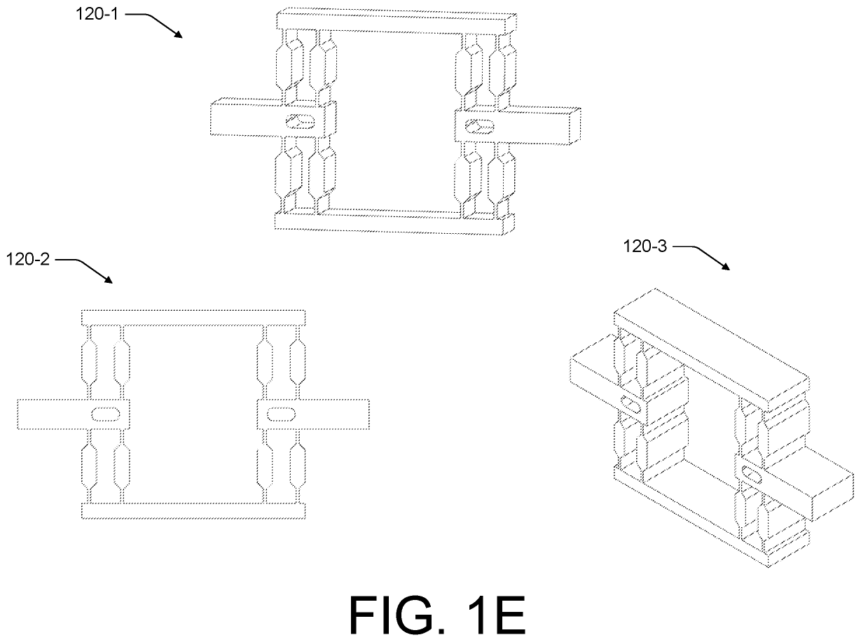

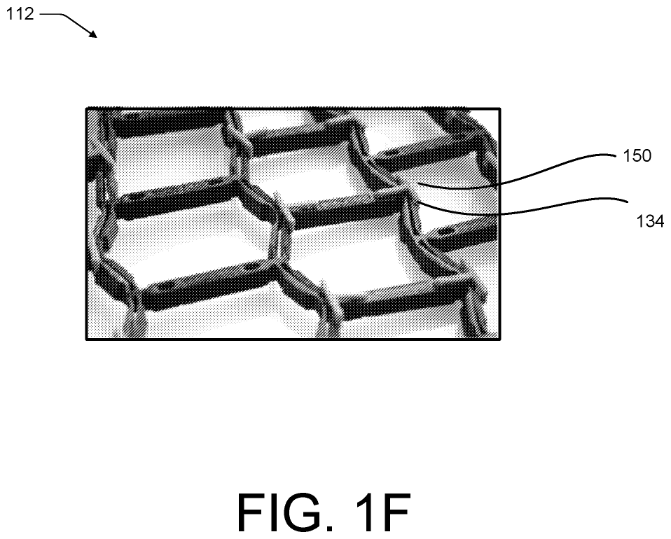

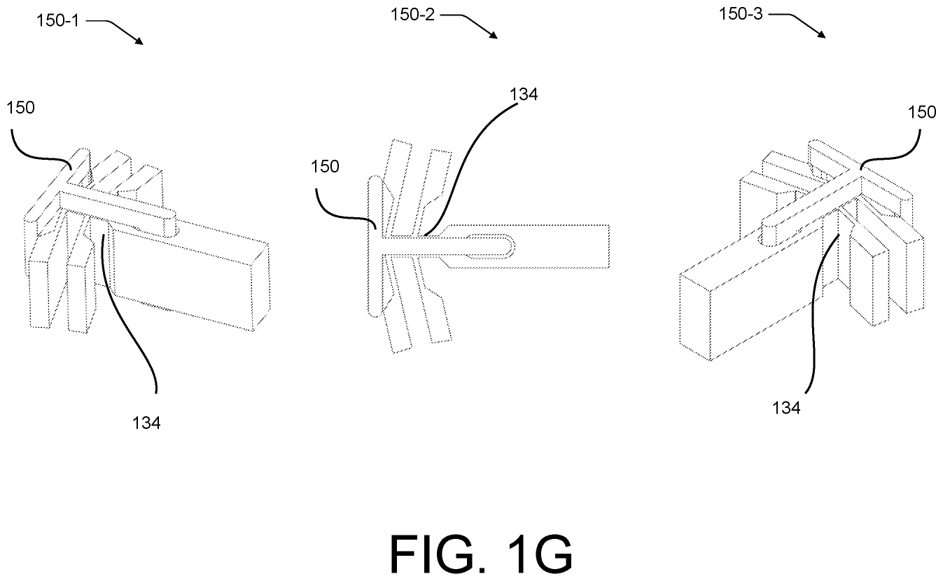

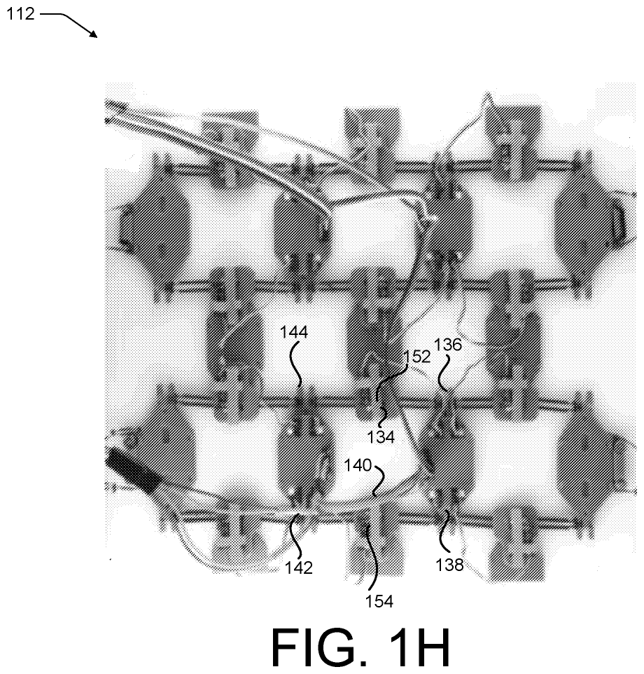

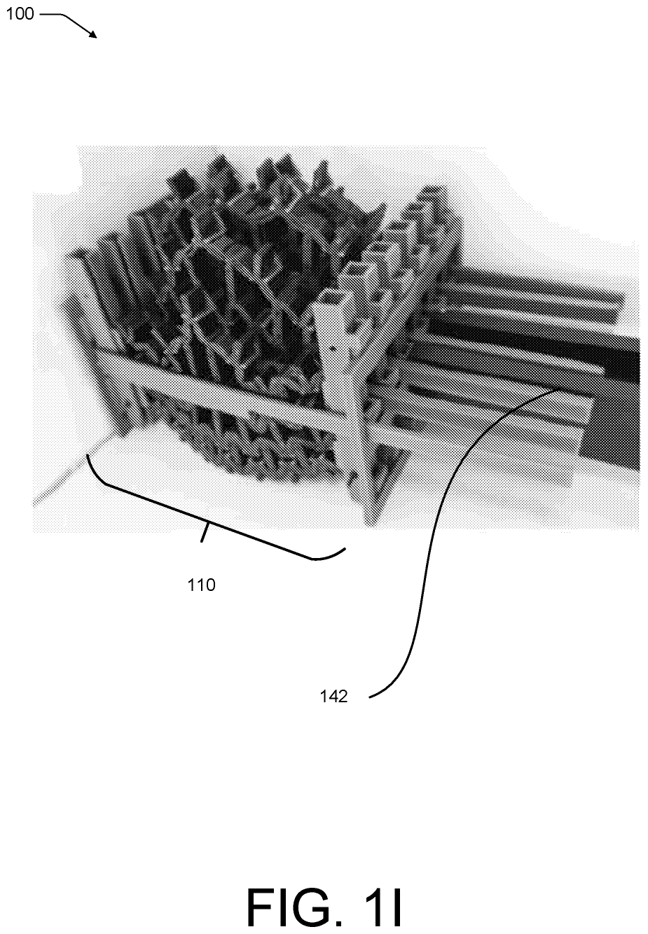

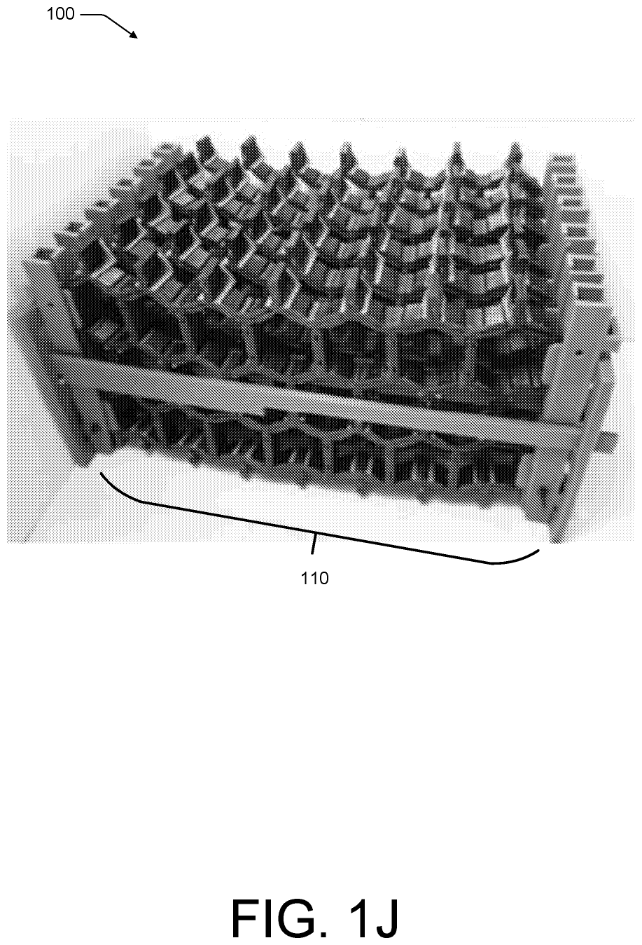

FIG. 1A illustrates a schematic diagram of an example reprogrammable system 100 according to implementations of this disclosure. In FIG. 1A, there are three axes including a first axis 102, a second axis 104, and a third axis 106. In implementations, the first axis 102, the second axis 104, and the third axis 106 are perpendicular or substantially perpendicular to each other. In implementations, “substantially” means to a great or significant extent. In implementations, “substantially perpendicular” means within an 85-95 degree angle, within an 87-93 degree angle, or within an 89-91 degree angle. A person skilled in the art would understand “substantially perpendicular” in the context of this disclosure.

Referring to FIG. 1A, the reprogrammable system 100 has a first side 108 configured to be reprogrammable in at least a first direction. In implementations, the first side is configured to be reprogrammable to display a profile/heightmap in the first direction. The first direction is along the first axis 102, either in a positive direction or in an opposite direction. In implementations, the first side 108 may include multiple caps such as the first cap 1082. The multiple caps may be used for visualization. Additional details of the first side 108 and caps are discussed hereinafter. The first side 108 is formed by a reprogrammable structure 110 having one or more layers stacked along a second direction along the second axis 104.

FIG. 1B illustrates various views of the reprogrammable system 100 according to implementations of this disclosure. 100-1 shows a first view of the reprogrammable system 100. 100-2 shows a second view of the reprogrammable system 100. 100-3 shows a third view of the reprogrammable system 100.

FIG. 1C illustrates a schematic diagram of the reprogrammable structure 110 of the reprogrammable system 100 according to implementations of this disclosure. Referring to FIG. 1C, the reprogrammable structure 110 has a first layer 112, a second layer 114, . . . and an nth layer 116, where n is a positive integer. Though FIG. 1C shows more than one layer, there may be a single layer in the reprogrammable structure 110. In some instances, when the reprogrammable structure 110 has one layer, the first side 108 is an edge of the layer. In some instances, when the reprogrammable structure 110 has multiple layers, the first side 108 is a 3D surface.

FIG. 1D illustrates a schematic diagram of an example individual layer (such as the first layer 112) according to implementations of this disclosure. In implementations, the example individual layer (such as the first layer 112) may be implemented with auxetic reprogrammable structures. Additional details of auxetic reprogrammable structures are described hereinafter. Referring to FIG. 1D, the example individual layer (such as the first layer 112) has repeating individual unit cells. Here, the first layer 112 is used as an example of an individual layer, and it should be understood that other layers (if any) may have the same reprogrammable structure and function as the first layer 112. In implementations, the repeating unit cells may have the same reprogrammable structure.

Bubble 118 shows an expanded view of an example individual unit cell (first unit cell) 120. The first unit cell 120 has multiple elements, for example, a first element 122, a second element 124, a third element 126, a fourth element 128, a fifth element 130, and a sixth element 132. The first element 122 and the second element 124 are connected by a first connecting joint 134. The second element 124 and the third element 126 are connected by a second connecting joint 136. The third element 126 and the fourth element 128 are connected by a third connecting joint 138. The fourth element 128 and the fifth element 130 are connected by a fourth connecting joint 140. The fifth element 130 and the sixth element 132 are connected by a fifth connecting joint 142. The sixth element 132 and the first element 122 are connected by a sixth joint 144. Though FIG. 1D shows six elements and six joints in the first unit cell 120, the first unit cell 120 may include other numbers of elements and/or other numbers of joints. In some instances, the elements are formed of a noncompliant/rigid material. As an example, the elements are formed of thermoplastic polyurethane (TPU). In some instances, the elements are formed of a compliant material. In some instances, the connecting joints are formed of a compliant material. As an example, the connecting joints are formed of polylactic acid (PLA). In some instances, the connecting joints are living hinges. In some instances, the elements and the connecting joints may be fabricated by 3D printing.

A second unit cell 146 is adjacent to the first unit cell 120. The second unit cell 146 shares the second element 124, the first connecting joint 134, and the second connecting joint 136 with the first unit cell 120. In other words, the second element 124, the first connecting joint 134, and the second connecting joint 136 are also a part of the second unit cell 146. Additionally, a third unit cell 148 is also adjacent to the first unit cell 120. The third unit cell 148 shares the third element 126, the second connecting joint 136, and the third connecting joint 138 with the first unit cell 120. In other words, the third element 126, the second connecting joint 136, and the third connecting joint 138 are also a part of the third unit cell 148.

FIG. 1E illustrates various views of an example individual unit cell (such as the first unit cell 120) according to implementations of this disclosure. Referring to FIG. 1E, 120-1 shows a first view of the example individual unit cell (such as the first unit cell 120). 120-2 shows a second view of the example individual unit cell (such as the first unit cell 120). 120-3 shows a third view of the example individual unit cell (such as the first unit cell 120).

The reprogrammable system 100 can be programmed manually or electrically/robotically. If the reprogrammable system 100 is programmed manually, biasing blocks are inserted into the unit cells, effectively biasing the connecting joints to buckle in a specific direction. If the reprogrammable system 100 is programmed electrically/robotically, actuators are used to actuate/bias the connecting joints.

FIG. 1F illustrates an example individual layer (such as the first layer) 112 where the connecting joints are biased manually according to implementations of this disclosure. Referring to FIG. 1F, a biasing block 150 is inserted into the first connecting joint 134 to bias the first connecting joint 134 to buckle in a specific direction. FIG. 1G illustrates various views of the biasing block 150 according to implementations of this disclosure. Referring to FIG. 1G, 150-1 shows a first view of the biasing block 150. 150-2 shows a second view of the biasing block 150. 150-3 shows a third view of the biasing block 150. Additional details of the biasing block are described hereinafter.

FIG. 1H illustrates an image of a part of an example individual layer (such as the first layer) 112 where the connecting joints are biased electrically/robotically according to implementations of this disclosure. Referring to FIG. 1H, the example individual layer (such as the first layer) 112 further has actuators. A first actuator 152 is coupled to the first connecting joint 134. The first actuator 152 is configured to actuate the first connecting joint 134. A second actuator 154 is coupled to the fourth connecting joint 140. The second actuator 154 is configured to actuate the fourth connecting joint 140. In some instances, there are no actuators coupled to the second connecting joint 136, the third connecting joint 138, the fifth connecting joint 142, and/or the sixth connecting joint 144. Additionally or alternatively, there may be actuators coupled to the second connecting joint 136, the third connecting joint 138, the fifth connecting joint 142, and/or the sixth connecting joint 144. In implementations, the actuators may include mechanical actuators, electric actuators, magnetic actuators, electromechanical actuators, thermal actuators, hydraulic actuators, and so on. As an example, an individual actuator has a servo motor. As an example, an individual actuator has a linear servo motor. Additional details of actuators are described hereinafter. The system 100 further has a controller (not shown) configured to control the actuators.

FIG. 1I illustrates an image of the reprogrammable system 100 (without caps) in an extended state according to implementations of this disclosure. Referring to FIG. 1I, the reprogrammable system 100 further has a global force applying device 142 configured to apply a global force to the reprogrammable structure 110. As an example, the global force applying device 142 has a stepper motor. The global force has a compressive force and/or an extending force. The reprogrammable system 100 has an extended state and a compressed state (expressed state). In FIG. 1I, the reprogrammable structure 110 is in the compressed state. FIG. 1J illustrates an image of the reprogrammable system 100 (without caps) in an extended state according to implementations of this disclosure. In implementations, the reprogrammable structure 110 is programmed when the reprogrammable structure 110 is in the extended state. The first side 108 is further configured to display a profile when the reprogrammable structure 110 is in the compressed state (expressed state).

In implementations, the reprogrammable system 100 may include more than one reprogrammable sides. In some instances, the reprogrammable system 100 may further include a second side (not shown) configured to be reprogrammable in a direction different from the first direction. For example, the second side may be opposite to the first side. For example, the reprogrammable system 100 may further include a third side (not shown) configured to be reprogrammable in a direction different from the first direction. For example, the third side may be adjacent to the first side.

With the reprogrammable system 100, small nudges can shift the local and/or the global Poisson's ratio of the reprogrammable system, causing the first side of the reprogrammable system take on different shapes under a global compressive force. By actively biasing/actuating the connecting joints, the reprogrammable system can produce a reprogrammable first side that does not require inputs to maintain shape and can display arbitrary 2D information and/or take on complex 3D shapes. Such a reprogrammable system opens new opportunities in micro devices, tactile/haptic displays such as braille displays, manufacturing, and robotic systems.

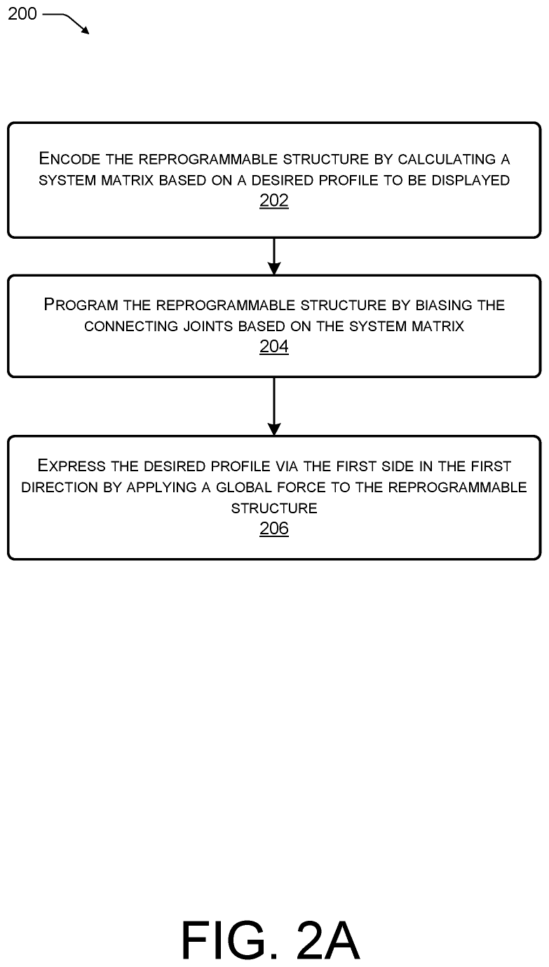

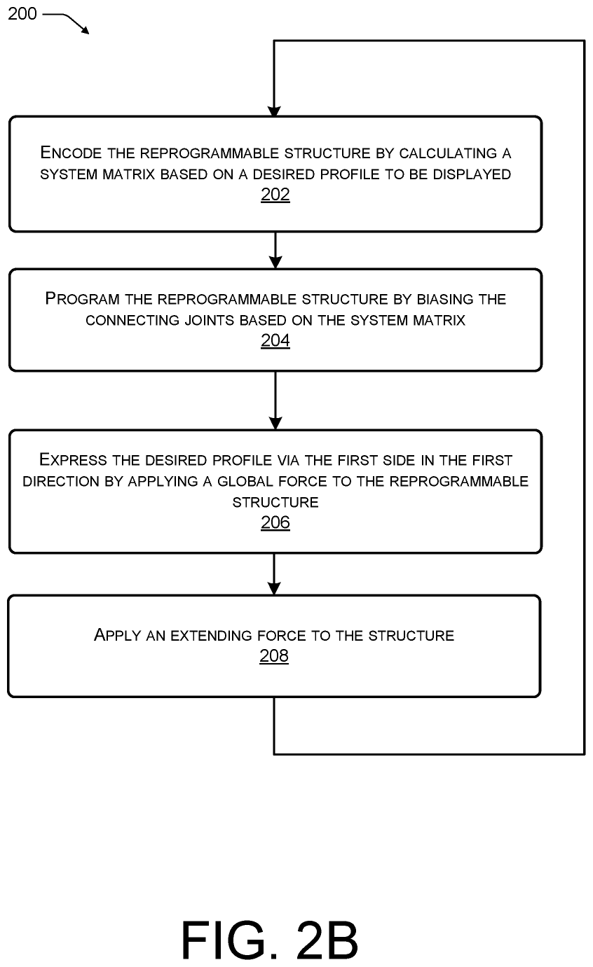

FIG. 2A and FIG. 2B illustrate a flowchart of an example process 200 for controlling the reprogrammable system 100 according to implementations of this disclosure. Referring to FIG. 2A, the process 200 has the following operations.

At 202, operations include encoding the reprogrammable structure by calculating a system matrix based on a desired profile to be displayed. The system matrix has joint values for connecting joints, and wherein an individual joint value defines an angle between two elements connected by an individual connecting joint. In implementations, encoding the reprogrammable structure further comprises slicing the desired profile into coordinate points. In implementations, the desired profile comprises a binary pattern. Additional details of how to calculate the system matrix are described hereinafter.

At 204, operations include programming the reprogrammable structure by biasing the connecting joints based on the system matrix. in implementation, the reprogrammable structure can be programmed manually and/or electrically/robotically. In some instances, biasing the connecting joints comprises controlling an individual actuator to actuate/bias a connecting joint to which the individual actuator coupled, to bias the connecting joint. Additional details of how the actuators actuate/bias the connecting joints are described hereinafter. In some instances, biasing the connecting joints comprises inserting a biasing block into the connecting joint. Additional details of how to bias the connecting joint by inserting a biasing block into the connecting joint are described hereinafter.

At 206, operations include expressing the desired profile via the first side in the first direction by applying a global force to the reprogrammable structure. In implementations, the global force is a compressive force. In implementations, applying a global force to the reprogrammable structure comprises determining a magnitude of the global force. Additional details of how to determine the magnitude of the global force are described hereinafter. In some instances, the global force is in the third direction, which is along the third axis 108, either in a positive direction or an opposite direction. In some instances, the global force is between 0 Newton (N) non-inclusive to 0.7 N inclusive.

Referring to FIG. 2B, the process 200 further has the following operations.

At 208, operations include applying an extending force to the reprogrammable structure and reprograming the reprogrammable structure by repeating the operations of 202, 204, and 208.

With the process 200, small nudges can shift the local and/or the global Poisson's ratio of the reprogrammable system, causing the first side of the reprogrammable system take on different shapes under a global compressive force. By actively biasing/actuating the connecting joints, the reprogrammable system can produce a reprogrammable first side that does not require inputs to maintain shape and can display arbitrary 2D information and/or take on complex 3D shapes. Such a reprogrammable system opens new opportunities in micro devices, tactile/haptic displays such as braille displays, manufacturing, and robotic systems.

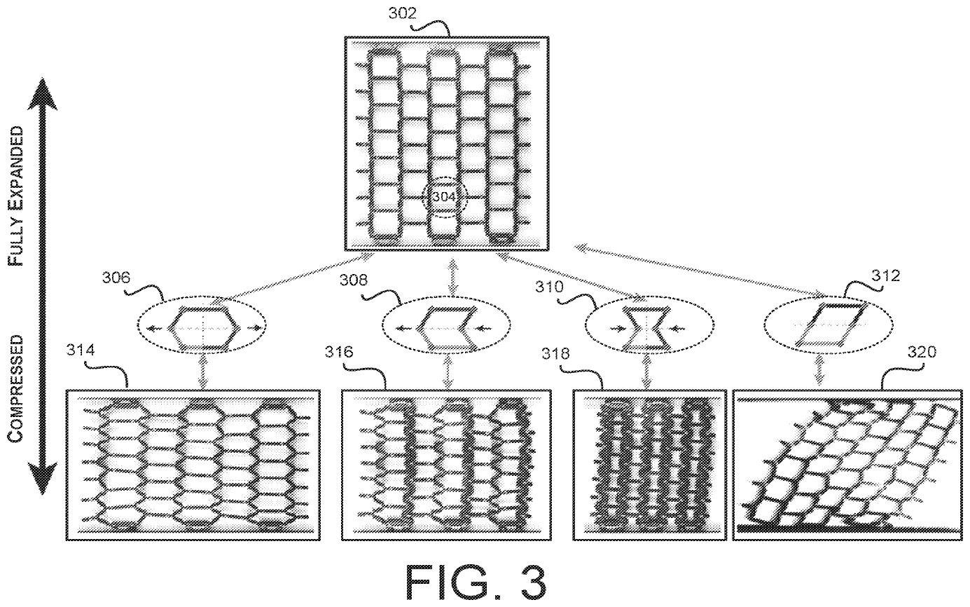

FIG. 3 illustrates induced global changes in Poisson's ratio of an example auxetic structure (lattice) according to implementations of this disclosure. Because auxetic structures have multiple accessible low energy states, it offers the possibility to mechanically reprogram the structure to a desired configuration. When the lattice (auxetic structure) is fully extended, all that is required to define the corresponding compressed state is a simple, low energy mechanical nudge to constrain each joint. By carefully selecting the state of every joint, it is then possible to reprogram the structure in a way that encodes both shape and mechanical properties.

Referring to FIG. 3, 302 shows fully expanded lattice (auxetic structure) acts as an intersection point from which it can be compressed into 4 separate modes. An individual unit cell 304 can be adjusted to have a positive (hexagon) Poisson's ratio 306, zero (arrowhead) Poisson's ratio 308, or negative (hourglass) Poisson's ratio 312. The shear element (parallelogram) 312 also allows lateral shifts between the top and bottom of the lattice (auxetic structure). Experimental data shows the relationship between axial and lateral deformation and the calculation of the average Poisson's ratio. 314 shows the lattice (auxetic structure) in a positive state with a positive Poisson's ratio. 316 shows the lattice (auxetic structure) in a zero state with a zero Poisson's ratio. 318 shows the lattice (auxetic structure) in a negative state with a negative Poisson's ratio. 320 shows the lattice (auxetic structure) in a shear state with a zero Poisson's ratio.

Referring to FIG. 3, the lattice (auxetic structure) can be considered as an array of 4 cell types. Three of the cell types compress axially without any shearing and have either a Poisson's ratio that is positive, negative, or zero. By biasing every joint in the lattice to match one cell type, the global Poison's ratio of the material can be adjusted.

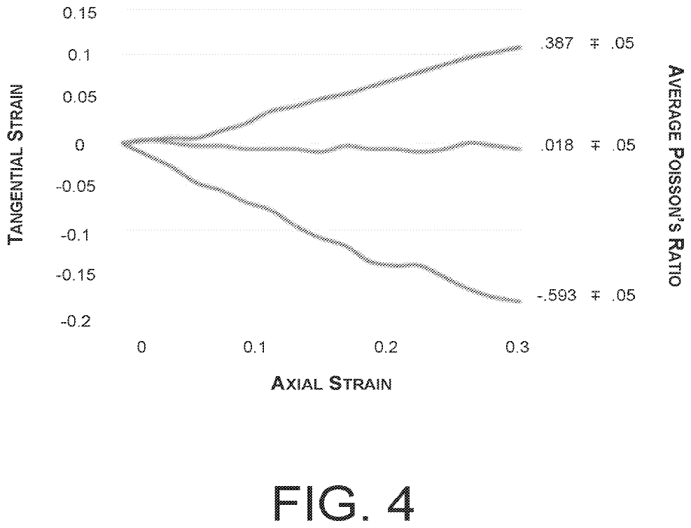

FIG. 4 illustrates experimental data showing the relationship between axial and lateral deformation and the calculation of the average Poisson's ratio. Testing 3D printed TPU structures yielded experimental results for average global Poisson's ratios in the 3 compressed global configurations (Referring to FIG. 4). The material (auxetic structure)'s effective Poisson's ratio can be adjusted by alternating the cell type between columns (e.g., 3 columns made up of positive cells and 2 columns of negative cells will produce a specific effective Poisson's ratio). However, attempting to alternate the cell types between adjacent rows of cells will result in a discontinuity along the edge of the material (auxetic structure), causing mechanical frustration and failure. To regionally adjust Poison's ratio in the material (auxetic structure), the final cell type becomes a necessary component. By adjusting the two sides of the cell to stay parallel, it becomes an effective means of bridging the differences in cell width as the structure is compressed. This cell can be considered the “shear” element, and it can be used to adjust the properties of the material beyond simple global shifts.

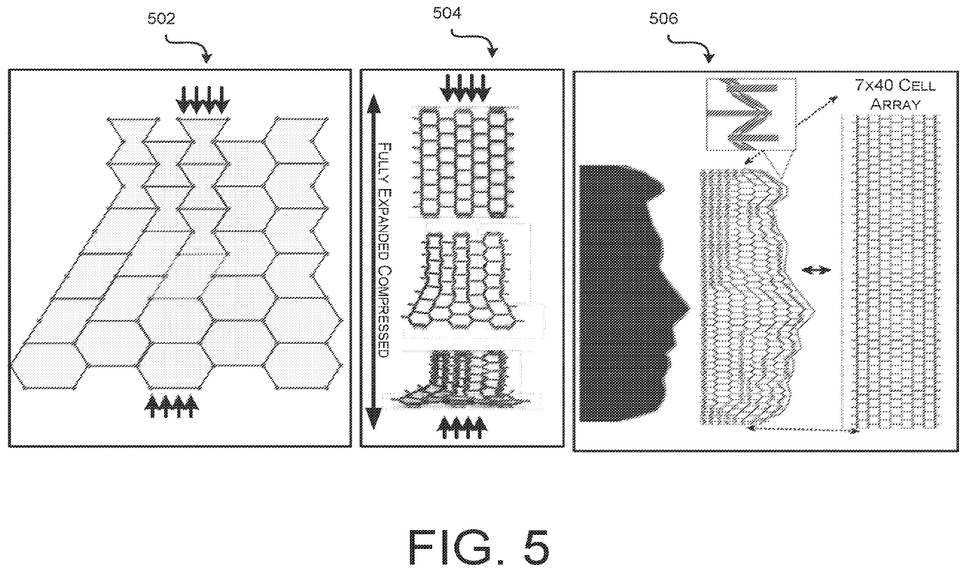

FIG. 5 illustrates profile generation in biased metamaterial (auxetic structure) according to implementations of this disclosure. Referring to FIG. 5, 502 shows that compressed 2D lattice structure demonstrates regional differences in Poisson's ratios. A 3D printed TPU lattice (auxetic structure). 504 shows that the auxetic structure can be biased and deforms with regional Poisson's ratios when compressed. 506 shows that Finite element simulation demonstrates a structure with a larger cell count (7×40) can be biased and compressed to match a specific profile.

By leveraging the shear element in the auxetic structures, it is possible to adjust regional shifts in Poisson's ratio throughout the material (referring to 502). Since unit cells with positive Poisson's ratios will expand out laterally, and in relation, cells with negative Poisson's ratios will contract in, it is possible to not only adjust material properties, but also the shape of the material. This relationship allows generating complex profiles as the material is compressed by simply nudging the interior joints with small forces.

Generating complex profiles using buckling lattices (auxetic structures) presents an interesting phenomenon. Considering the arrays to be combinations of 4 cell types is convenient at small cell counts. However, as the number of joints increases, more detailed consideration of the design space is needed to encode valuable information. For most arbitrary joint combinations, the constraints within the lattice structure itself will create disagreements in the lattice (auxetic structure) that result in mechanical frustration. For example, in a 5×5 array of cells, if every joint is individually set to a position of 0 or 1, there exist 33554432 possible combinations. Of those possibilities, 13464 will result in a valid configuration of joints. To find the set of all valid solutions, a set of rules can be established. Lattices (auxetic structures) can be organized as an array of vertical joint values. Additional details are described hereinafter.

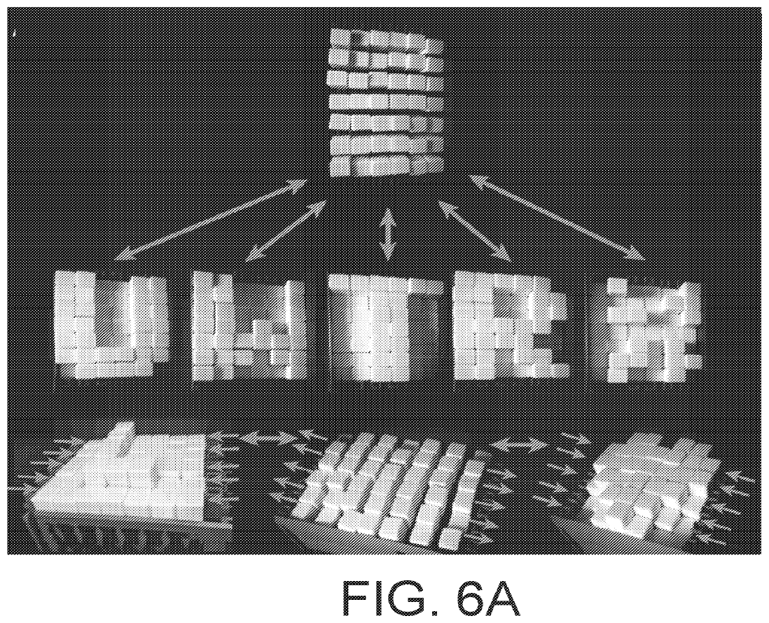

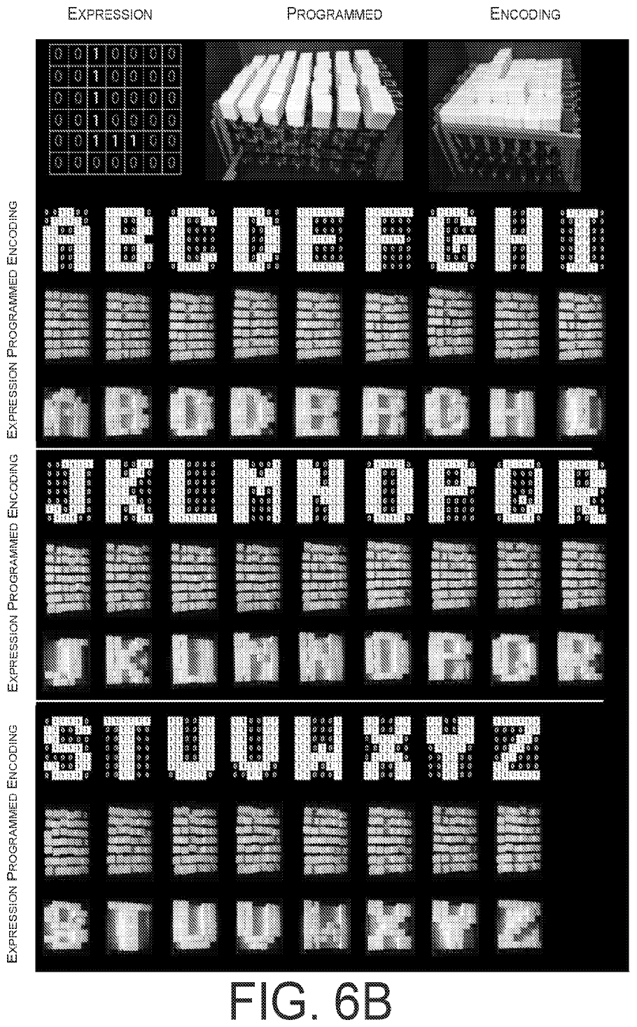

FIG. 6A illustrates reprogrammable height field according to implementations of this disclosure. Referring to FIG. 6A, 602 shows that a reprogrammable multi-layered structure can display information through binary changes in surface height to represent letters in the English alphabet or braille letters. The multi-layered structure can represent both binary height changes and multi-level changes in height. FIG. 6B illustrates a binary surface reprogramming according to implementations of this disclosure. Referring to FIG. 6B, 3D reprogrammable surface structure transitions to display every letter in the English alphabet.

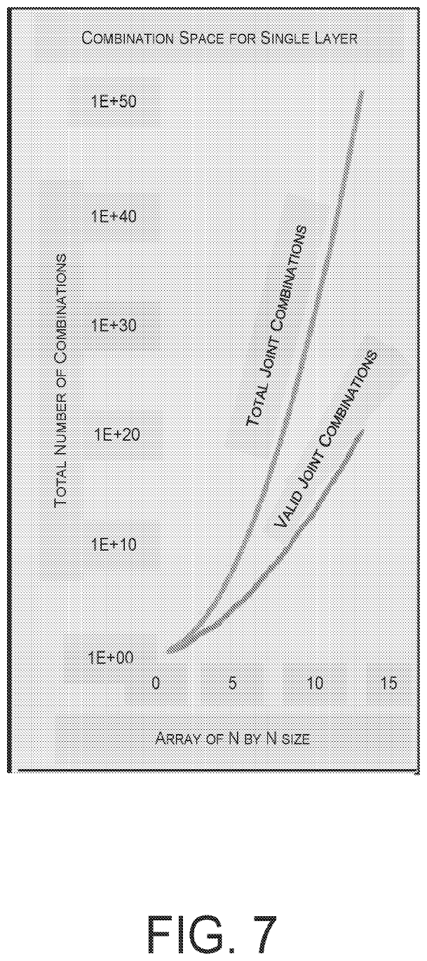

FIG. 7 illustrates a graph showing the combined space for a single layer of an auxetic structure. Referring to FIG. 7, as the array size increases, the total number of possible configurations exponentially expands.

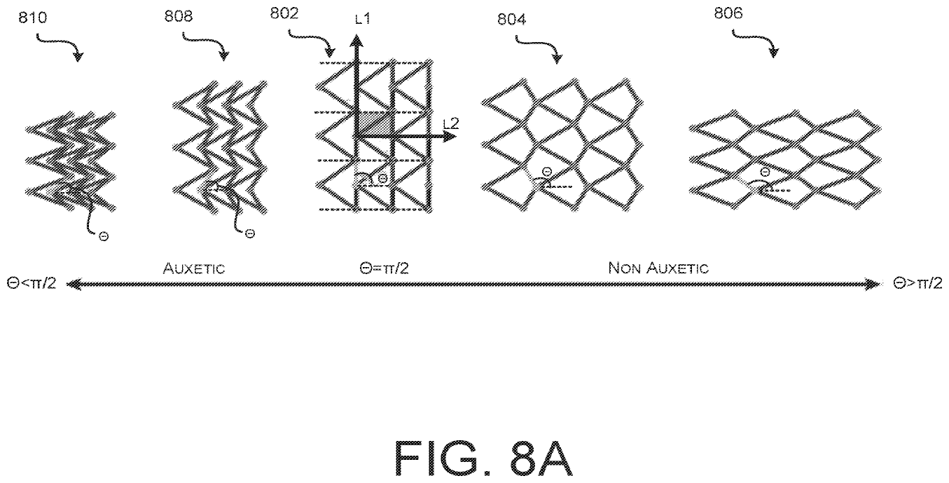

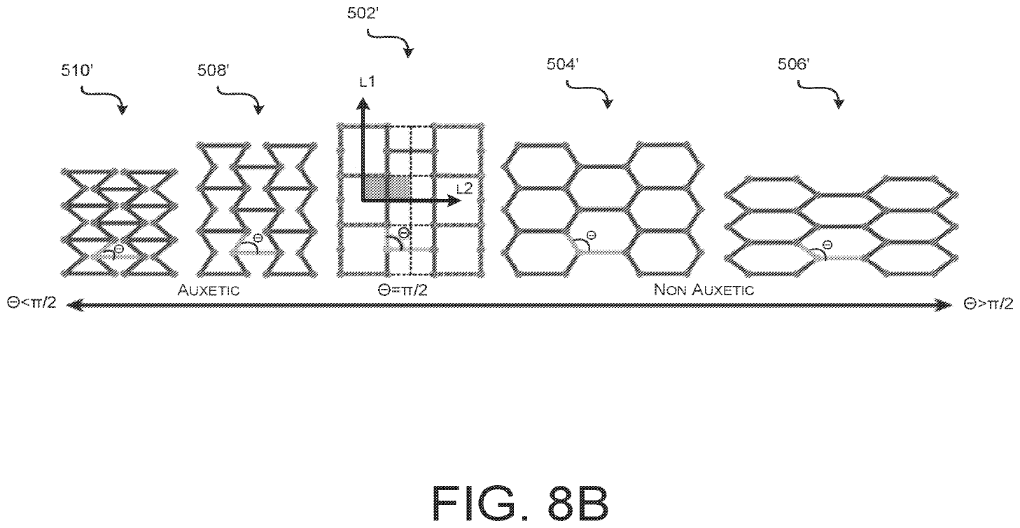

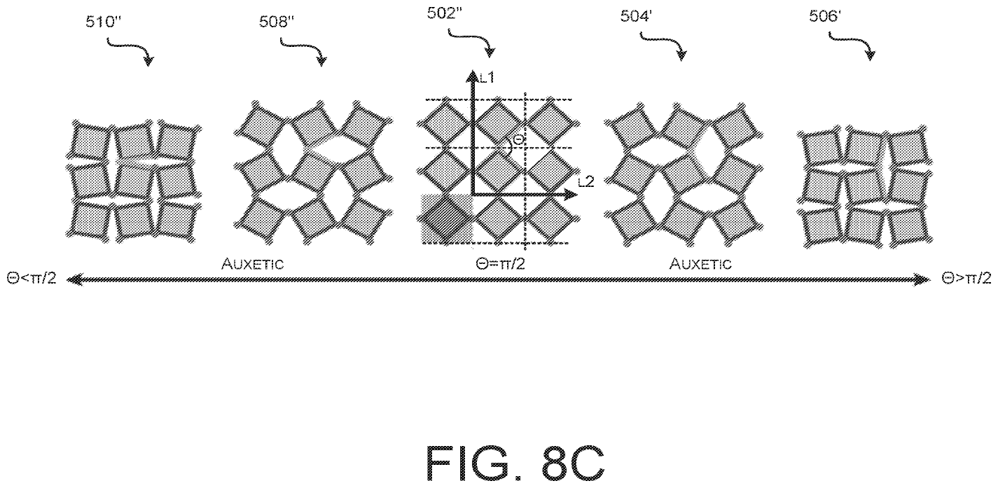

FIG. 8A illustrates a first type of auxetic structure with double arrowhead unit cells according to implementations of this disclosure. FIG. 8B illustrates a second type of auxetic structure with reentrant honeycomb unit cells according to implementations of this disclosure. FIG. 8C illustrates a third type of example auxetic structure with rotating square unit cells according to implementations of this disclosure.

Many variations of auxetic structures exist, but of these geometries, only a few types of auxetic structures exhibit the switching capability. Auxetic structures that can be shown to have this switching ability are auxetic structure with reentrant honeycomb unit cells [22] (referring to FIG. 8B) and the auxetic structure with double arrowhead unit cells [26] (referring to FIG. 8A).

Referring to FIG. 8A, 802 shows a state of the first type of auxetic structure where each unit cell is in the most/fully extended state where θ=π/2. 804, 806, 808, and 810 show the states of the first type of auxetic structure as the first type of auxetic structure is compressed and begins to deform both axially and laterally. For the first type of auxetic structure with the switching ability, the lateral deformation is altered by the direction with which the connecting joints collapse as they buckle. If the connecting joints buckle such that θ<π/2 (808 and 810), then the first type of auxetic structure shrinks in the lateral direction, making the first type of auxetic structure auxetic. If the connecting joints buckle such that θ>π/2 (804 and 806), then the first type of auxetic structure extent laterally and ceases to display auxetic behavior.

Referring to FIG. 8A, 802′ shows a state of the second type of auxetic structure where each unit cell is in the most/fully extended state where θ=π/2. 804′, 806′, 808′, and 810′ show the states of the second type of auxetic structure as the second type of auxetic structure is compressed and begins to deform both axially and laterally. For the second type of auxetic structure with the switching ability, the lateral deformation is altered by the direction with which the connecting joints collapse as they buckle. If the connecting joints buckle such that θ<π/2 (808′ and 810′), then the second type of auxetic structure shrinks in the lateral direction, making the second type of auxetic structure auxetic. If the connecting joints buckle such that θ>π/2 (804′ and 806′), then the second type of auxetic structure extent laterally and ceases to display auxetic behavior.

Many auxetic structures also exist but do not exhibit the switching ability. Referring to FIG. 8C, the third type of auxetic structure with rotating square unit cells is one such example that remains auxetic as θ changes throughout the full possible deformation. 802″ shows a state of the third type of auxetic structure where each unit cell is in the most/fully extended state where θ=π/2. 804″ and 806″ show the states of the third type of auxetic structure when the third type of auxetic structure is compressed where θ>π/2. 808″ and 810″ show the states of the third type of auxetic structure when the third type of auxetic structure is compressed where θ<π/2. As the third type of auxetic structure is deformed under compression, the third type of auxetic structure remains auxetic regardless of the direction in which the connecting joints buckle and collapse. In other words, no matter whether θ<π/2 or θ>π/2, the third type of auxetic structure remains auxetic.

By analyzing the trajectory of a unit cell, it is possible to classify a structure as a switching auxetic [29]. These patterns can be tiled infinitely by translating single unit cells repeatedly. Vectors I₁ and I₂ define the matrix L=[I₁,I₂], and denote the translational offset between a point on a unit cell and that same point on an adjacent unit cell. As θ changes, the unit cell transforms continuously, both shearing and scaling such that system matrix G=(g₁₁, g₁₂; 0, g₂₂). The instantaneous transformation of the reprogrammable system can be considered to be L_dot=G*L. Additionally details are described hereinafter.

Additionally, reentrant star auxetics [22] can also be shown to have this switching capability but the reentrant star auxetics may have too many degrees of freedom.

Hereinafter, some Examples are described. It should be understood that the following Examples are to explain and illustrate various aspects of this disclosure rather than limit this disclosure.

### Example 1

In this Example 1, the design and the fabrication of manually reprogrammable planner auxetic structures are discussed.

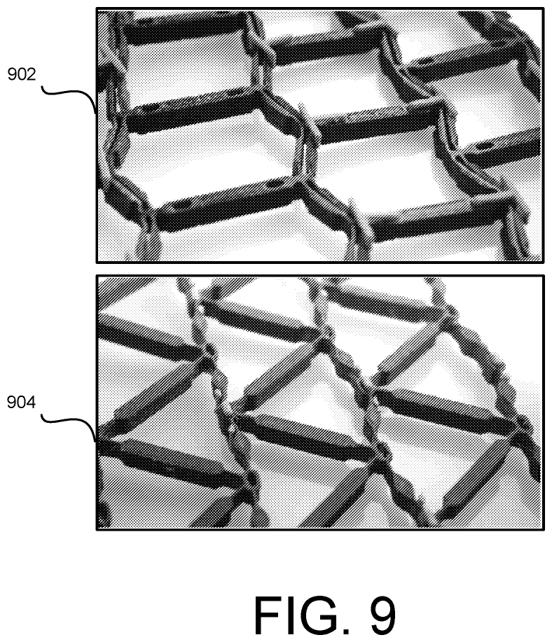

FIG. 9 shows images of the auxetic structure with reentrant honeycomb unit cells and the auxetic structure with double arrowhead unit cells according to implementations of this disclosure. Referring to FIG. 9, 902 shows an image of the auxetic structure with reentrant honeycomb unit cells. 904 shows an image of the auxetic structure with double arrowhead unit cells.

To create both the auxetic structure with double arrowhead unit cells and the auxetic structure with reentrant honeycomb unit cells, 3D printed unit cells with compliant connecting joints are designed. Elements of unit cells and connecting joints were 3D printed from Ninjaflex Thermoplastic Polyurethane (TPU) using a Creality Ender3 printer. The auxetic structures were designed using computer aided design (CAD) techniques. The planar auxetic structures were extruded to have a constant thickness of 6 mm. The noncompliant/rigid elements within the unit cells had a width of 3 mm and a length of 20 mm.

For the auxetic structure with reentrant honeycomb unit cells, Individual unit cells formed approximately 28×28 mm squares. The compliant connecting joints were designed as standard knife blade flexures with a length of 2.25 mm and a width of 0.44 mm.

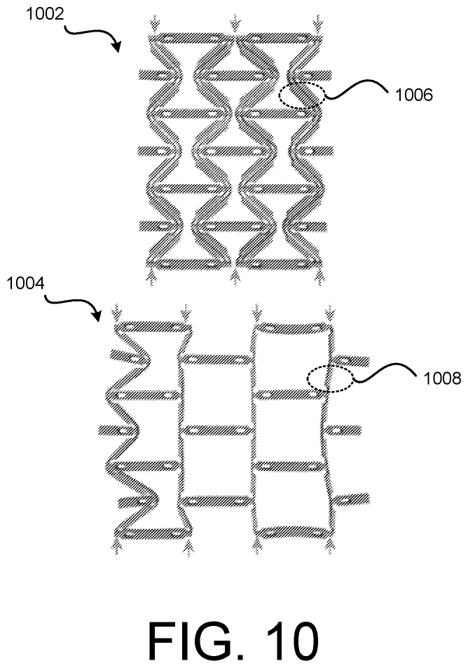

FIG. 10 illustrates FEA simulations to compare buckling of the auxetic structure with two bar elements (1002) versus the auxetic structure with single bar elements (1004) under predefined axial deformation and similar joint loading conditions. On initial testing of the auxetic structures, uneven deformation occurred due to a lack of complete constraints within the auxetic structures. To ensure that the auxetic structures collapse evenly throughout the entirety of the axial deformation, a two-bar element 1006 was implemented instead of a single bar element 1008. An FEA simulation of the two potential auxetic structures with fixed displacements in the vertical direction (such as the third direction 106) and similar loading conditions at each connecting joint. The results of the simulation showed much more predictable buckling within the auxetic structure with the two bar elements (1002). Constraints were also imposed on the boundaries of the auxetic structures. To ensure an even compression of the auxetic structure, the two-bar elements were used.

The auxetic structures could be reprogrammed by inserting biasing blocks into the unit cells, effectively biasing/actuating the connecting joints to buckle in a specific direction. The biasing blocks were printed out of PLA using the Creality Ender 3 printer.

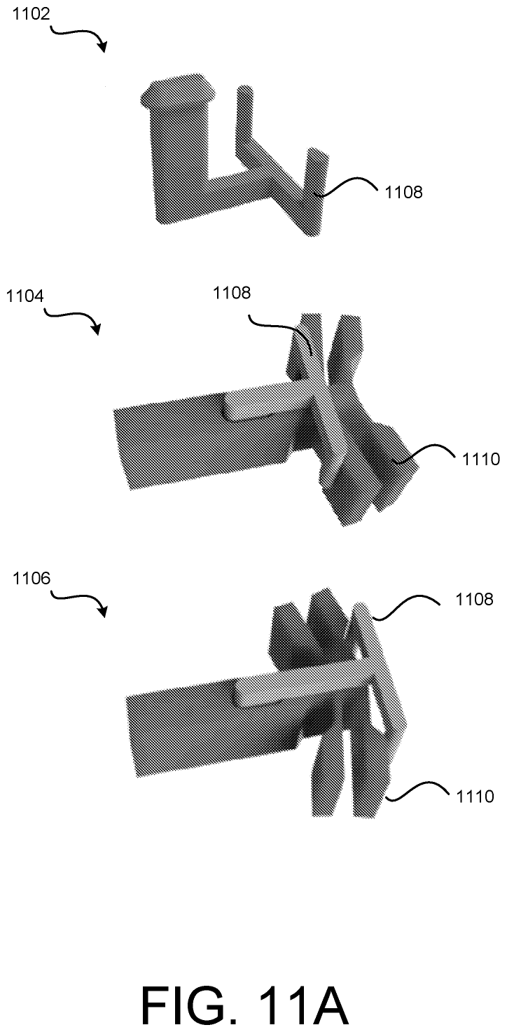

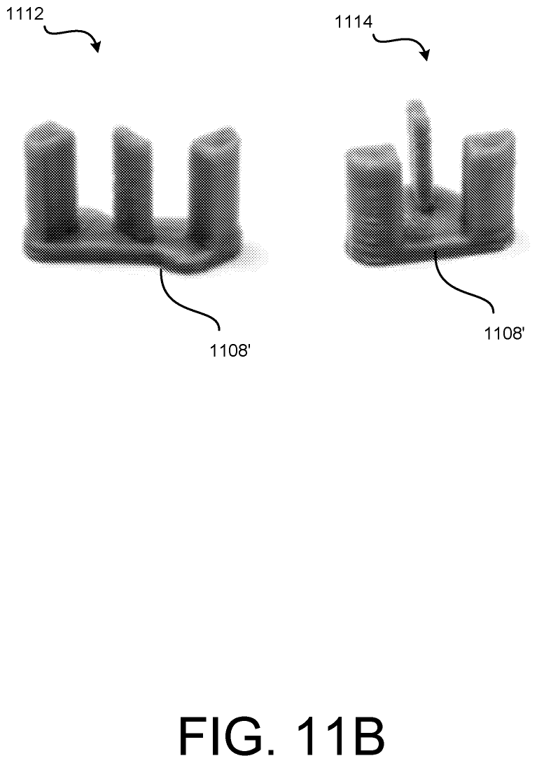

FIG. 11A illustrates design 1102 and the application scenarios 1104 and 1106 of an example biasing block according to implementations of this disclosure. Referring to FIG. 11A, 1102 shows the design of the biasing block 1108. The biasing block 1108 is configured to bias the connection joints of the auxetic structures under compressive deformation. In implementations, the biasing block 1108 can be fabricated by 3D printing using polylactic acid (PLA). 1104 shows an application scenario of the biasing block 1108, where the biasing block 1108 is inserted into a first position in the connecting joint 1110. 1106 shows another application scenario of the biasing block 1108, where the biasing block 1108 is inserted into a second position in the connecting joint 1110. The connecting joint 1110 is biased differently indifferent application scenarios as shown in 1104 and 1106. The biasing block 1108 deformed the connecting joint approximately 1.3 mm and was rotated 1110 degrees to switch the biasing angle from θ>π/2 to θ<π/2.

FIG. 11B illustrates different views of an alternate biasing block 808′. Referring to FIG. 11B, 812 shows a first view of the alternate biasing block 808′, and 814 shows a second view of the alternate biasing block 808′. the alternate biasing block 808′ was used to lock the joint angle to be compatible with the shear cell configuration. For example, the alternate biasing block 808′ was 3D printed with PLA using a Creality Ender3 printer.

It should be understood that the materials used to fabricate the connecting joints, the elements, and the biasing blocks are examples, other materials that are suitable for fabricating the connecting joints, the elements, and the biasing blocks can be used. The dimensions of unit cells and elements are examples, and other dimensions of unit cells and elements can be used. This disclosure is not limited thereto.

### Example 2

In this Example 2, the design and the fabrication of electrically reprogrammable planner auxetic structures are discussed. For real-world applications, it will be important to automate the biasing step (actuating step) to quickly shift the auxetic structures between profiles. To demonstrate that these auxetic structures could be robotically reprogrammed, a planar auxetic structure with honeycomb unit cells was created.

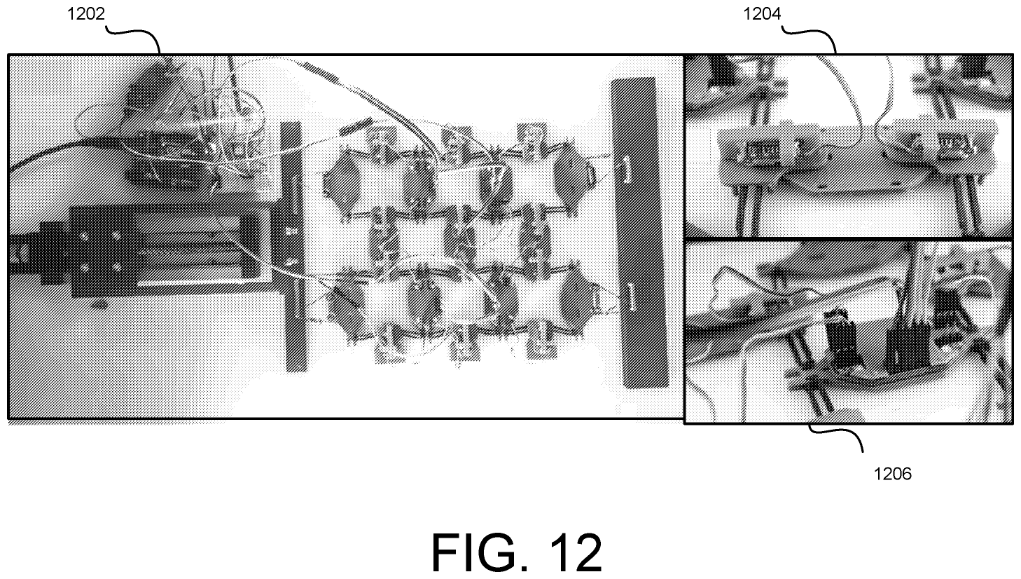

FIG. 12 illustrates the design and the fabrication of electrically reprogrammable planner auxetic structures. Referring to FIG. 12, 1202 shows a setup of electrically reprogrammable planner auxetic structures. 1204 shows linear servo motors. 1206 shows a mounted set of linear servo motors to actuate/bias the connecting joints. 1206 shows a mounted and connected printed circuit board (PCB) surrounded by linear servo motors it is controlling. In the setup shown in 1202, actuators, for example, Mgaxyff analog micro linear servo motors, were used to actuate/bias the connecting joints rather than manually inserting the biasing blocks. For sake of simplicity, this setup was built using 12 linear servo motors driven by chained PCBs and controlled by a controller (such as an Arduino). Compliant connecting joints were 3D printed from TPU filament, and unit cell elements were 3D printed from PLA. The connecting joints were biased by sliding a plate with cantilevered posts which could be shifted to limit the buckling conditions of an individual unit cell. This setup includes a 3 by 3 unit cell count, which was large enough to demonstrate global and local changes in Poisson's ratio. This setup acted as a proof of concept for automated switching. More complex profiles could be generated with a similar structure, and more cells would need to be included. It should be understood that the materials used to fabricate the connecting joints and the elements are examples, other materials that are suitable for fabricating the connecting joints and the elements can be used. The numbers of unit cells and linear servo motors are examples, and other numbers of unit cells and linear servo motors can be configured. This disclosure is not limited hereto.

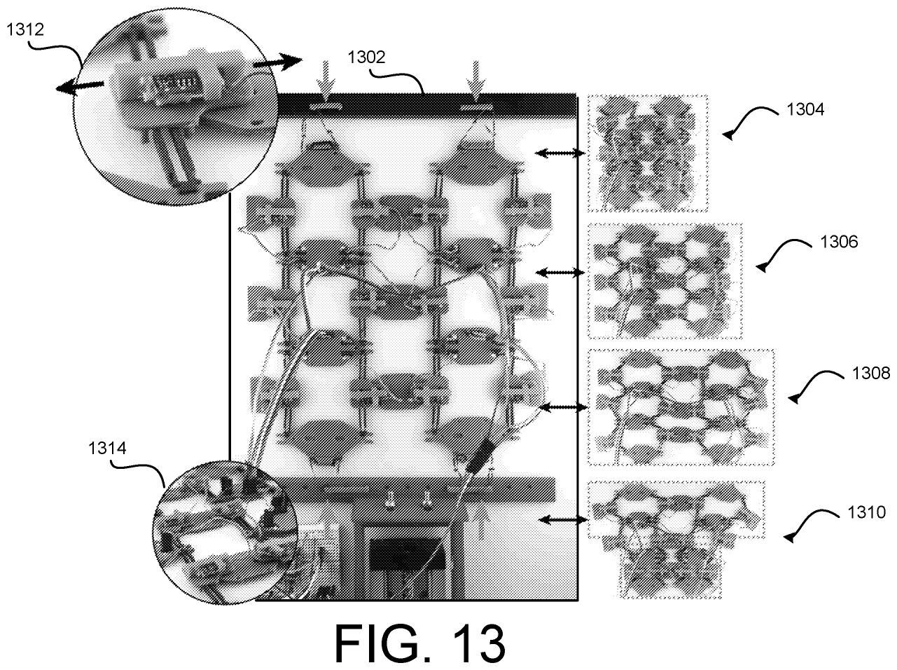

FIG. 13 illustrates scenarios of robotically switching the electrically reprogrammable planner auxetic structures. Referring to FIG. 13, 1302 shows a scenario where the auxetic structure was in a natural state, a stepper motor applied a global compressive force to the auxetic structure, and individual connecting joints were programmed using an array of linear servo motors. 1304, 1306, 1308, and 1310 show scenarios where the auxetic structure is programmed to buckle into multiple different configurations/states. 1304 shows a scenario where the auxetic structure is programmed to buckle into a configuration/state with a global negative Poisson's ratio. 1306 shows a scenario where the auxetic structure is programmed to buckle into a configuration/state with a global zero Poisson's ratio. 1106 shows a scenario where the auxetic structure is programmed to buckle into a configuration/state with a global positive Poisson's ratio. 1310 shows a scenario where the auxetic structure is programmed to buckle into a configuration/state with a vertical transition in Poisson's ratio from positive to negative. Bubble 1312 shows an expanded view of a linear servo motor. Bubble 1314 shows an expanded view of several linear servo motors.

### Example 3

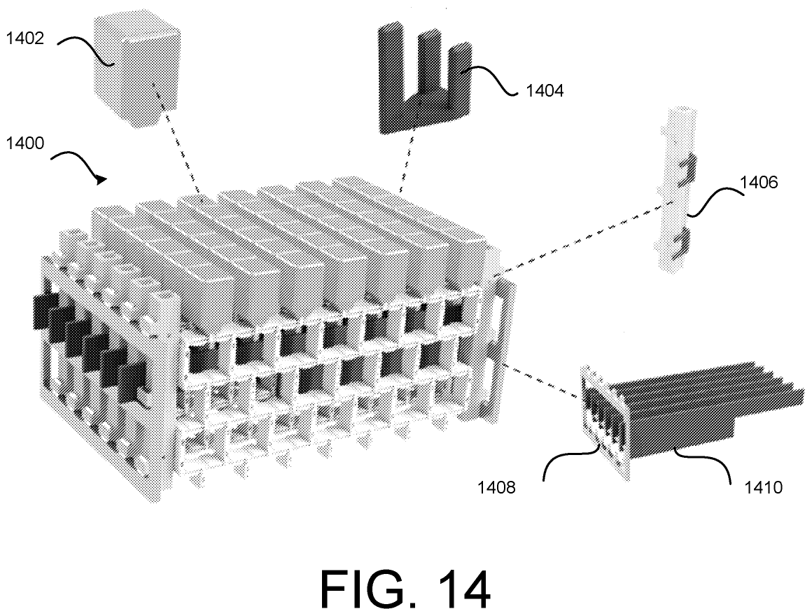

In this example 3, the design and the fabrication of an example 3D reprogrammable system is discussed. FIG. 14 illustrates a 3D reprogrammable system 1400 according to implementations of this disclosure. To fabricate the 3D reprogrammable system 1400, multiple layers of the 2D planar auxetic surface were constructed and combined using a 3D printed PLA rack system 1400. To create a smooth surface when the 3D reprogrammable system 1400 is compressed, multiple caps (such as cap 1402) were mounted on one side of the multilayer structure. For example, the caps can be 3D printed using PLA. Like the planar auxetic structures, biasing blocks (such as the biasing block 1404) were inserted into the unit cells to actuate/bias individual connecting joints. The 3D reprogrammable system 1400 included rail component 1406 with roller bearings. As an example, the rail component 1406 can be 3D printed using PLA. The unit cells at the boundaries were connected to roller bearings that fit inside the rail components. One point of the rail component 1406 was fixed to one side of a boundary unit cell. The other connections between the boundary unit cells and the rail component 1406 were rolling connections to allow for sliding edge conditions. To reduce unwanted movement in the horizontal direction, spacers 1408 were positioned between each layer of the auxetic structure. As an example, rack 1410 was made from modular 3D printed parts that snapped into the rack system. The final reprogrammable system 1400 was reconfigured/reprogramed many times to create a variety of different surface designs/profiles.

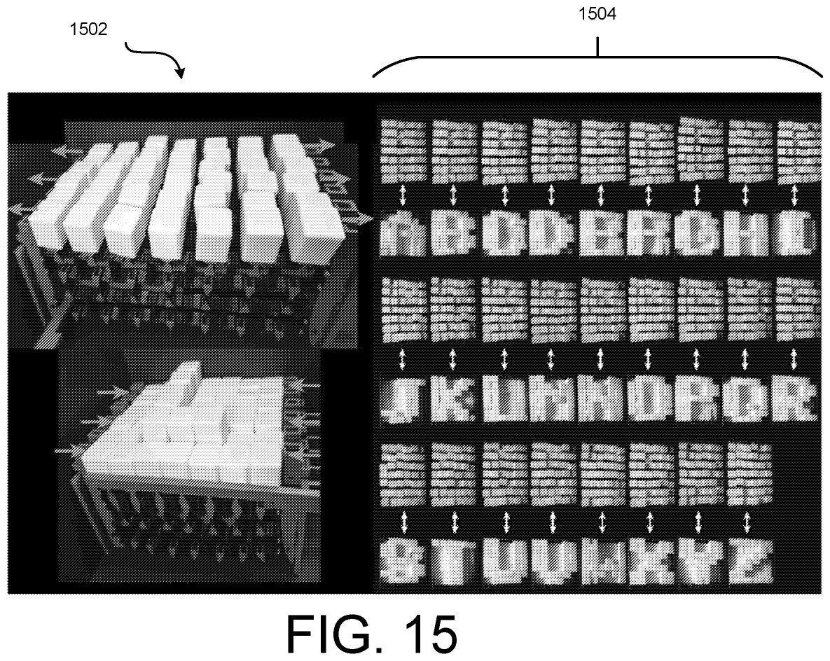

FIG. 15 illustrates binary surface reprogramming according to implementations of this disclosure. Referring to FIG. 15, 1502 shows a full view of the 3D reprogrammable structure. 1504 shows the structure transitions to display every letter in the English alphabet. Among other designs, it was possible to generate every letter in the English alphabet (Referring to FIG. 15). It was also possible to generate every character in the braille alphabet and a wide variety of multilevel designs.

It should be understood that the materials used to fabricate the rail components are examples, other materials that are suitable for fabricating the rail components can be used. This disclosure is not limited thereto.

### Example 4

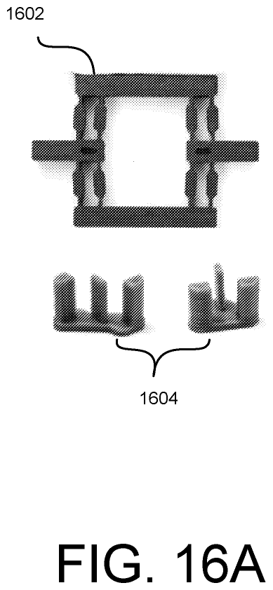

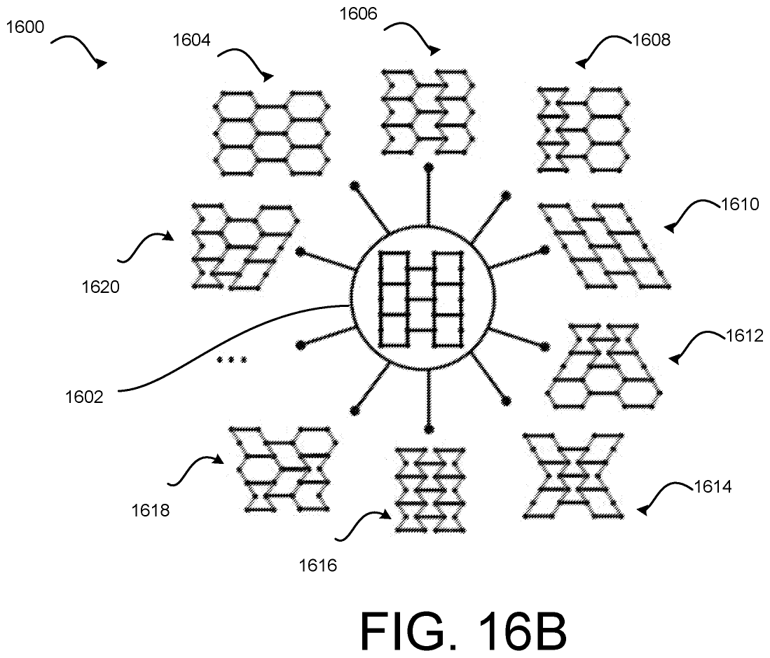

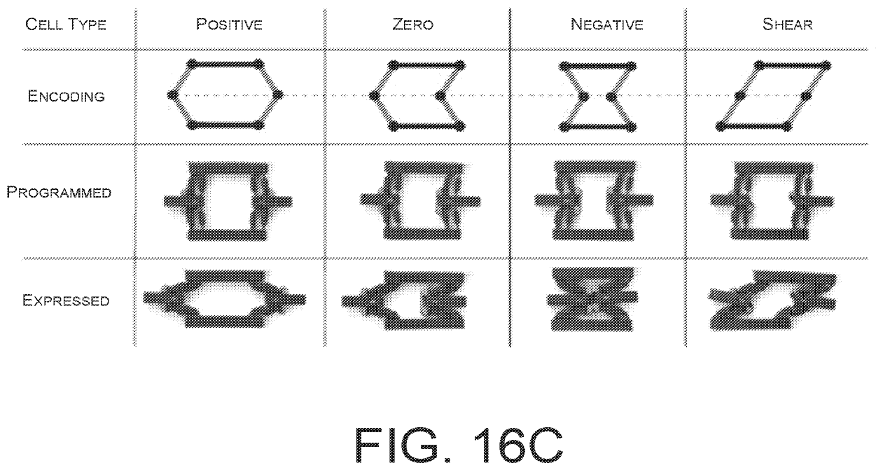

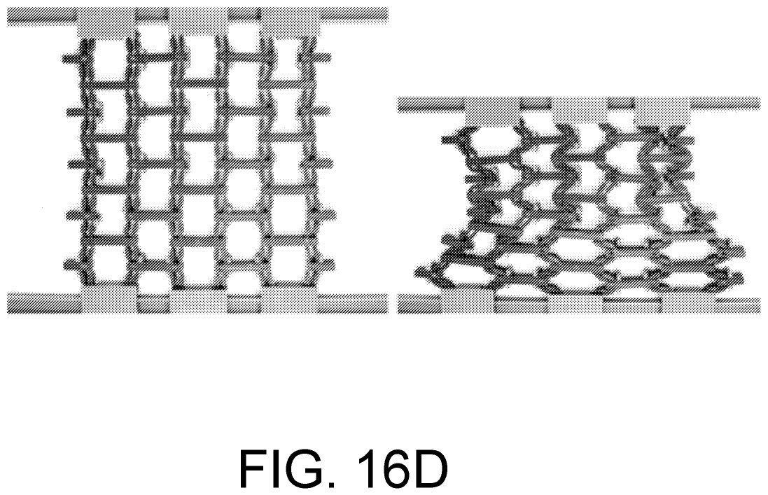

In this Example 4, reprogrammable surfaces through star graph metamaterials are discussed. FIG. 16A illustrates a single compliant 4-bar unit cell (1602) and 3D printed blockers for constraining the deformation of the cell (1604). FIG. 16B illustrates reprogrammable star graph configuration. An A×B lattice with A=6 and B=4 vertical linkages can transition into 6642 different valid configurations, matching a star graph structure (referring to Example 4). FIG. 16C illustrates that a single 2×2 linkage unit cell can be reprogrammed to 4 cell types (6 including mirrors), each with different mechanical properties. FIG. 16D illustrates that encoding different unit cells throughout a structure enables complex deformations of a 3D printed lattice.

Mechanical metamaterials can demonstrate unusual properties based on their architected periodic structure [18]-[21]. They are often represented as a graph of links that are embedded in a space [22], [23]. This space can be finite as in a sphere [24], closed like a cylinder [25], or infinite and open as in a plane [26], [27] or 3D space [15], [22], [26]. The embedding of the link graph reduces the infinite degrees of freedom of a plane or space filled with links into a small finite number of degrees of freedom. In the case of auxetic metamaterials, the number of degrees of freedom reduces to a single degree of freedom θ, often an angle between two links, that defines the evolution of the system [25]. This θ defines a trajectory of states, where the system must kinematically evolve by either increasing or decreasing θ, and the range of θ determines the limits of the system's deformation [25].

To enable programmable surface changes, the researchers developed metamaterial structures that have multiple trajectories, each representing a different surface profile, and provide a means for moving between these kinematic trajectories. The key concept for enforcing transitions between these trajectories is physically constraining mechanical singularities (FIGS. 16A-16D). Mechanical singularities are often viewed as terrible states for a system and normally should be avoided. Many quantities become infinite or indeterminate at these points. The canonical example is gimbal lock, where two Euler angles become degenerate, and it is impossible to disentangle the two angles. In robotics, a singularity in a joint may require infinite joint velocities to maintain a smooth movement or could generate infinite inverse-kinematic solutions.

### Results

The researchers present a subset of lattices that can be actively controlled to morph between valid physical states by leveraging this property of mechanical singularities. For certain materials, there are a series of different state trajectories that represent valid embeddings of the link graph. Each of these trajectories has a single degree of freedom θ, which is typically an angle between links. Each possible physical embedding is a node in a star graph network with a single state acting as the central node 1602 (referring to FIG. 16B). At this central node 1602, all trajectories converge to a single point characterized by a mechanical singularity.

At this singularity, an N by M tiling of cells goes from a single degree of freedom to N×(M+1) degree of freedom system. The spontaneous emergence of these degrees of freedom is what makes this point unpredictable. The singular point is metastable [28] so small nudges can adjust the angles between links, transitioning the system between state trajectories. These small local nudges effectively program the path of the system (referring to FIG. 16C). As moving away from the singular point, the structure develops multistability, where several low energy states exist with a high energy barrier separating them. Global compression guides the system along a selected path to reach an expressed state (referring to FIG. 16C).

The number of valid embeddings with a single degree of freedom is limited. Many combinations will result in geometric restrictions, causing the system to become frustrated [10], [29]. For a given combination of joint orientations to be valid, link lengths must be preserved throughout the system as θ evolves. A configuration can be validated by analyzing horizontal joint displacements at maximum compression to ensure that horizontal link lengths are preserved.

Different physical embeddings of a link graph structure produce a bulk material response with different mechanical properties. As has been reported in the literature, the double arrowhead or the honeycomb patterns can achieve the extremal global Poisson's ratios of positive one half and negative one along with zero Poisson's ratio [20]. The global Poisson's ratios can be varied between +0.5 and −1 by establishing strips of the same cell type over rows of the lattice. The ratio of cell types governs the magnitude of Poisson's ratio. Therefore, as seen in FIG. 16B the system can achieve a discrete number of values and transition between them at the node state (1604, 1606, 1608, 1610, 1612, 1614, 1616, 1618, AND 1620). The striping of various embeddings can also be used to produce preprogrammed profiles with a vase-like nature [11], [30].

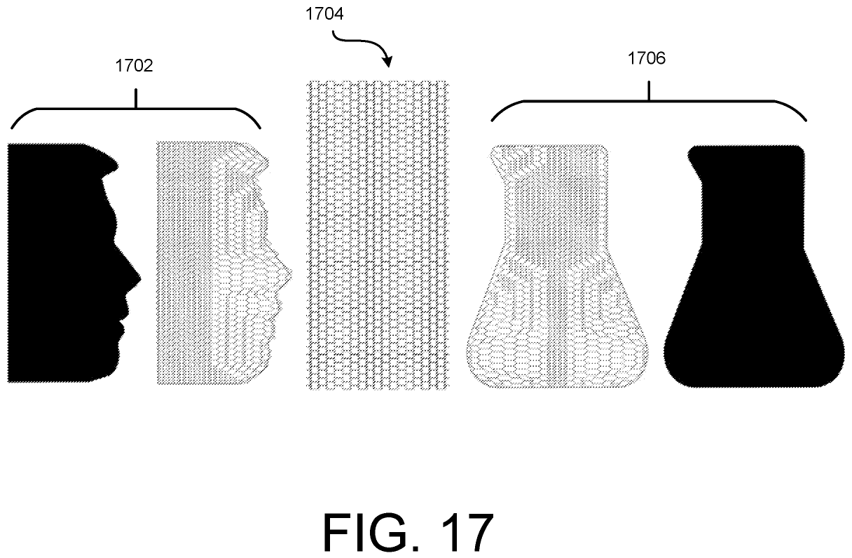

Generating arbitrary profiles requires a cell to be capable of both positive and negative Poisson's ratios and to have a shearing state. The shear element (referring to FIG. 16C) represents a completely different response that is not defined by Poisson's ratio. Therefore, a lattice must have at least one auxetic state trajectory, a transition point between auxetic and non-auxetic, and the ability to have a shear mode. The researchers found that the honeycomb patterns fit all the criteria for a programmable link structure. As demonstrated in FIG. 16D the shear response can connect regions with positive and negative Poisson's ratios, enabling spatially varying shape changes throughout the material. If no shearing layers are included, attempting to alternate cell types between adjacent horizontal rows will result in discontinuities along the edge of the material, causing geometric frustration and failure. The shear cell is a necessary topological component to bridge the difference in cell width and generate complex profiles (referring to FIG. 17).

FIG. 17 illustrates complex shape generation according to implementations of this disclosure. Referring to FIG. 17, 1702 shows that algorithmic profile generation allows approximating a flat-backed face profile by programming 17×41 cell lattice. 1704 shows that the extended state of the lattice acts as the central node of a star graph with many possible programmable trajectories. 1706 shows that the same 17×41 cell lattice is encoded to match the shape of a beaker with asymmetric profiles on each side.

For a honeycomb tiling with A×B vertical linkages, the total number of possible combinations is 2^{A×B}. Each vertical linkage is encoded as either a positive or negative value which corresponds to its slope as it compresses. To guarantee a frustration free trajectory [10], all linkage lengths must remain constant throughout the deformation of the system. To test the validity of any state, the researchers created an algorithm to verify if an encoding maps to a valid configuration (referring to Examples 5-17). Using a brute force application of this validity test, the researchers experimentally found the number of total valid states for all lattice combinations with A*B less than 50. By fitting this data to the general equation 2^{k}^{₁}^{AB+k}^{₂}^{(A+B)+k}^{₃} the researcher obtained k1=0.2989, k2=0.6924, k3=−1.3831 (referring to Examples 5-17). Following this trend, the number of valid states grows quickly but the probability of randomly selecting a valid configuration from the transition state rapidly approaches zero as the size of the tiling grows. For a 10×10 array, there are approximately 5.62E12 valid states but 1.2677E30 possible combinations. Hence, the probability of selecting a valid state at random is only 4.433E-16 percent.

The sparsity of valid trajectories necessitates active control through the singularity point to ensure successful transitions from state to state. To do this, the researchers developed an algorithm to designate the state of each linkage in a lattice, based on a predefined edge profile (referring to Examples 5-17). Starting at the defined edge, columns are generated such that they match the conditions enforced by the validity test and approach the desired profile on the opposing edge (referring to Examples 5-17). This strategy allows the researchers to generate complex profiles using large arrays to approximate detailed shapes (referring to FIG. 17).

To define the edge encoding of a high-resolution profile or function, the researchers deconstruct the shape into a series of line segments. The magnitude of the actuating compression determines the maximum slope of the vertical linkages. Combinations of multiple positive and negative elements allow edges to approximate intermediate slopes (referring to FIG. 17). These combinations of linkage slopes combine to generate complete profiles. With this model, the researchers can construct high complexity profiles such as the silhouette of a face (referring to FIG. 17, 1702) or a beaker (referring to FIG. 17, 1706). Using the lattice encoding algorithm described above, the researchers propagate this edge encoding backward through the structure to configure the full lattice shape.

To program these systems, vertical linkages must be mechanically biased to have either a positive or negative slope. The researchers used multiple strategies to mechanically encode trajectories, including mechanical inserts (referring to FIG. 16A) and small electromechanical actuators. To demonstrate real-time reprogrammability, the researchers constructed a lattice with distributed micro servos. A linear axis, paired with a stepper motor, applied an axial compressive load to the lattice to transition the system into a specified compressed state. Encoding mechanisms constrain two adjacent linkages (above and below), meaning that biasers only need to be included at every other joint to fully program the system. Because the programming and the actuation of these structures are decoupled, the joint biasing forces and displacements can be extremely small (˜0.7 N) in comparison to the compressed holding force (˜40 N). This opens a wide range of possible options for actively programming such as micro-actuators or shape-memory materials [3], [6], [12].

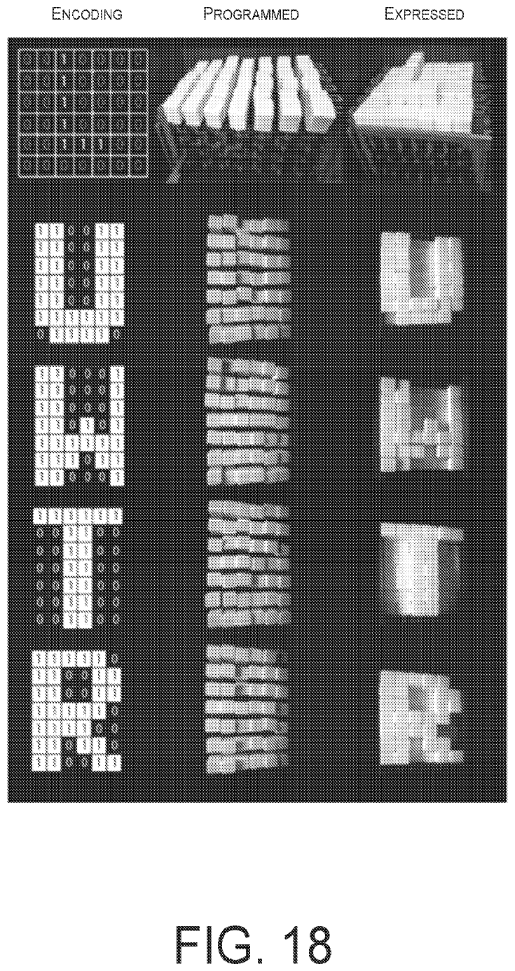

FIG. 18 illustrates binary information representation according to implementations of this disclosure. Multiple layers of the planar lattice structure are stacked, acting as a reprogrammable height map. Little variation can be seen between different physically programmed encodings. When the researchers compress the structure, the expression of the encoding becomes apparent.

Combining multiple layers of these 2D lattice structures produces reprogrammable binary height fields (referring to FIG. 18). To generate a binary pattern, each planar lattice only requires a single layer of reprogrammable linkages. From the expanded state, the trajectory of each pixel will map to a height of either 0 or 1 based on the state of each edge linkage. A R×S grid, with R lattice height and S being the number of layers, has a large design space with 2R×S valid combinations. FIG. 18 shows a binary height field with several encodings. The displacement required to bias each joint is very small in comparison to the deformation expressed through global actuation. Because of this, the physically programmed state shows little variation between encodings while the information becomes clearly visible in the expressed state. This display can render any 6×7 binary pixel value, allowing us to render the entire English alphabet in block letters or brail.

The researchers created reprogrammable 3D structures and surfaces by layering several planar structures in parallel. These structures can transform to generate both concave/convex curvatures and positive/negative space. Along the length of a layer, the individual height value between adjacent pixels cannot vary more than one unit step at a time. In between layers, no such restriction exists, and adjacent pixels can vary without encountering geometric frustration. Because of this relation, 3D profiles with large discontinuities in height can be approximated more accurately by aligning jumps in height with the inter-layer boundary. The main factors limiting surface profile representation are the depth/height of the design, the resolution of surface details, and the maximum slope of the design. Higher lattice cell counts would help to improve resolutions and slope can be governed by the cell geometry and the amount of compression.

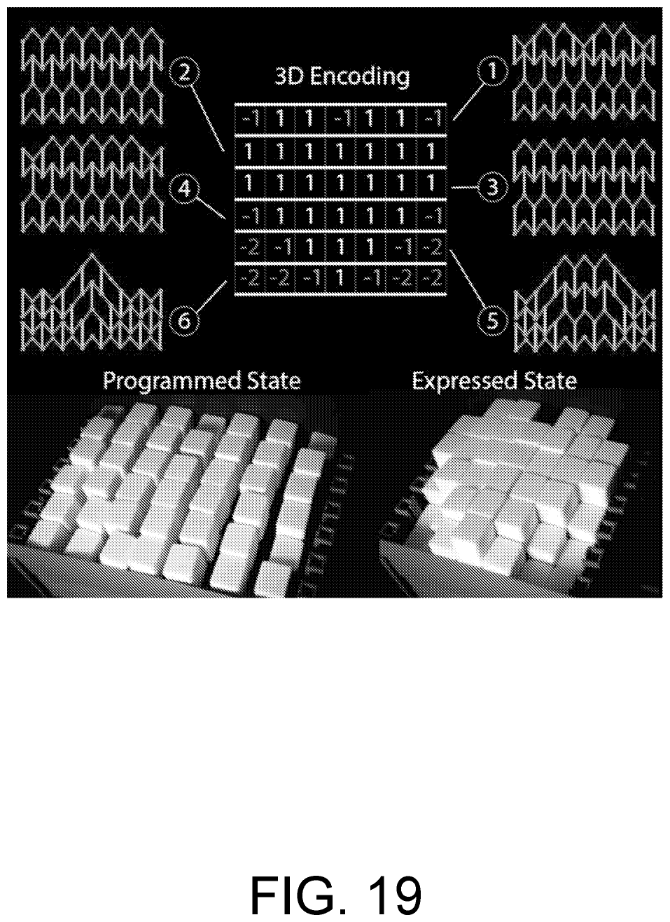

FIG. 19 illustrates 3D surface expression according to implementations of this disclosure. Stacking multiple star graph lattice structures creates reprogrammable 3D height maps. A surface height encoding corresponds to layers of programmed 2D structures. The physically encoded information is expressed by compressing the structure.

### CONCLUSION

The researchers have shown that metamaterials with star graph state trajectories can form the basis of reprogrammable surfaces. As demonstrated, specific combinations of programmable linkage angles within a lattice translate to mechanical shape changes in the structure. These structures have a convergent state of singularity, where all other valid states can be accessed. The compressive trajectories of these structures can be encoded using only small mechanical nudges to program the system. This approach supports a wide range of shape changes for both 2D and 3D structures. It decouples programming from actuation, creating opportunities for increased scalability and improved resolution. It also supports stable mechanical memory, needing no additional energy to hold a state once actuated. This concept is scale independent, allowing for the strategy to work at the scale of MEMS devices up to architectural surfaces. Shape changing interfaces offer opportunities to fundamentally change human-computer interaction through object simulation, communication of visual and tactile information, user augmentation, and extended reusability [1], [6]. Reprogrammable structures have utility in digitally adjustable tooling and jigs, variable friction materials, tunable acoustic surfaces [18], and robotic grippers, locomotion, and camouflage [16].

### Example 5

In this Example 5, materials and fabrication of the reprogrammable system are discussed. To create both the honeycomb and the arrowhead structures (referring to FIG. 9), the researchers designed 3D printed lattices with compliant joints. The researchers printed these from Ninjaflex Thermoplastic Polyurethane (TPU) using a Creality Ender3 printer. The lattices had a constant out of plane extrusion thickness of 6 mm. Rigid, vertical, and horizontal bars had a width of 3 mm and a length of 20 mm. For the reentrant honeycomb, Individual cells formed approximately 28×28 mm squares. The researchers designed compliant joint components as standard knife blade flexures with a length of 2.25 mm and a width of 0.44 mm. To ensure an even compression of the structure, the researchers replaced the single vertical linkages with two-bar linkages.

The researchers manually reprogrammed the trajectory state of the lattices by inserting 3D printed blocking elements into the TPU lattice structure, effectively biasing the joints to buckle in a specific direction (referring to FIG. 16A). The blocking element deformed the joint approximately 1.3 mm and was rotated 180 degrees to switch the biasing angle from θ>π/2 to θ<π/2. An alternate blocking element locked the joint angle to be compatible with the shear cell configuration (referring to FIG. 16A). The researchers printed these blocking elements out of PLA using a Creality Ender3 printer.

To Make the 3D structures, the researchers printed multiple 2D planar lattices and assembled supporting PLA components to make a layered rack system. To create a smooth surface when compressing the structure, the researchers mounted 19×22×30 mm PLA caps on one edge of the mechanism (referring to FIG. 14, 1402). The researchers connected the edges of each TPU lattice to rigid rails using small PLA components with roller bearings that moved freely (referring to FIG. 14) and maintained a 9.5 mm gap between sheets to avoid interference.

### Example 6

In this Example 6, mechanical tests for the reprogrammable system are discussed. To ensure smooth compression, the researchers fixed one cell on the top and bottom of the lattice to the compressing structure, establishing an origin in the lateral direction. The researchers connected the remaining cells to 10 mm bearings to create a sliding connection between the cells and the rigid surfaces. The researchers printed the compression structures out of PLA and actuated the system using a Nema 17 stepper motor and a motor mount position slide (McMaster Carr 6734K14). The samples rested on a Teflon sheet to reduce friction. The researchers tested the biasing force for a fully expanded unit cell and the holding force for a compressed unit cell in both tension and compression using an Instron mechanical test setup (referring to S12 in the pseudo code).

### Example 7

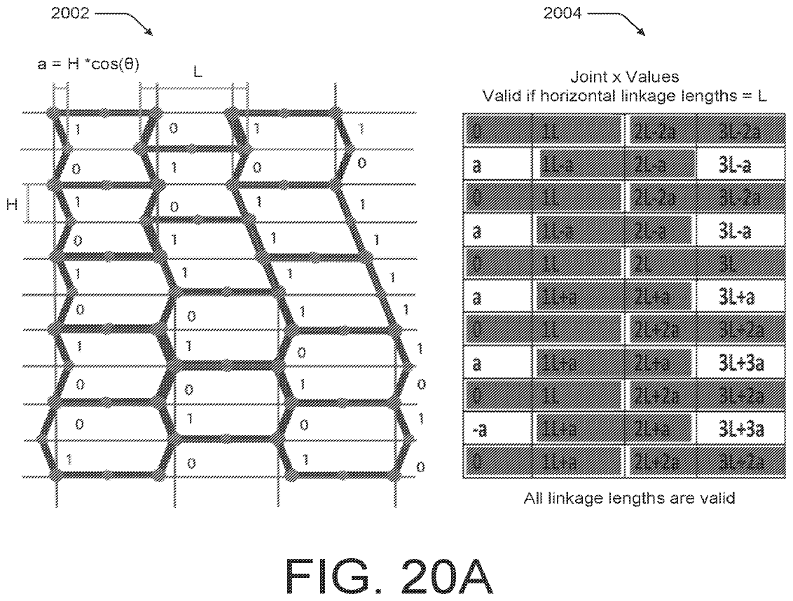

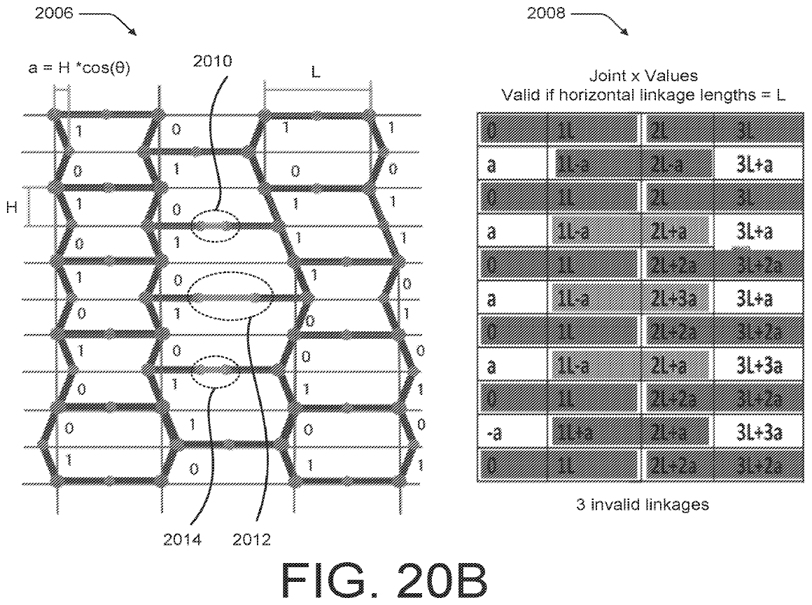

In this Example 7, conditions for valid unit cell configurations are discussed. FIG. 20A illustrates an example of valid structure combination check according to implementations of this disclosure. Referring to FIG. 20A, 2002 shows that slopes of vertical elements of the auxetic structure were encoded as either a 1 or a 0. Horizontal elements span alternating connecting joints. 2004 shows that the horizontal connecting joint position was used to verify that the unit cell maintains all horizontal element lengths (L). FIG. 20B illustrates an example of invalid structure combination check according to implementations of this disclosure. Referring to FIG. 20B, 2006 shows that lines 2010, 2012, and 2014 signify invalid element lengths. 2008 shows that the distance between connecting joints fails to equal the original element length (L) for three horizontal linkages, invalidating the configuration.

For a A×B reentrant honeycomb auxetic structure with vertical elements of length H, criteria were developed to test whether a given joint combination results in a valid state. A A represents the number of elements in the vertical direction, and B represents the number of elements in the horizontal direction. A 2D array of size A×B is populated with either 0s, denoting a negative slope, or 1 s, denoting a positive slope. Every possible valid state of the unit cell makes up a finite subset within the total 2A*B possible combinations of array values. Horizontal crossbars with a length of L alternate to connect every other grid point to the adjacent grid point, adding geometric constraints to the system. As the structure is compressed, all vertical linkages rotate to an angle ±θ, creating a horizontal offset of distance a=H*cos (θ). Starting from the top-left edge of the lattice (A, B=0), the researchers work across the top row and then down each column, populating a new array of size (A+1)×B with each joint's horizontal offset. Joint[0,0] is initialized to 0 and the remaining joint[0,1: B] horizontal offsets are calculated such that, if n is odd, joint[0, n]=joint[0, j−1]+L and if n is even, joint[0, j]=joint[0, j−1]+a_{i,j}+a_{i,j-1}. Every other horizontal offset is calculated by stepping down each column joint[1: A, B] and populating the array with joint[i, j]=joint[i−1, j]+ai−1,j (referring to FIG. 20A and FIG. 20B). After calculating these distances, researchers can check the validity of the structure by verifying that the joint value to the right side of each horizontal crossbar is equal to the vertex value to the left side of the horizontal bar plus the width of the crossbar (L).

### Example 8

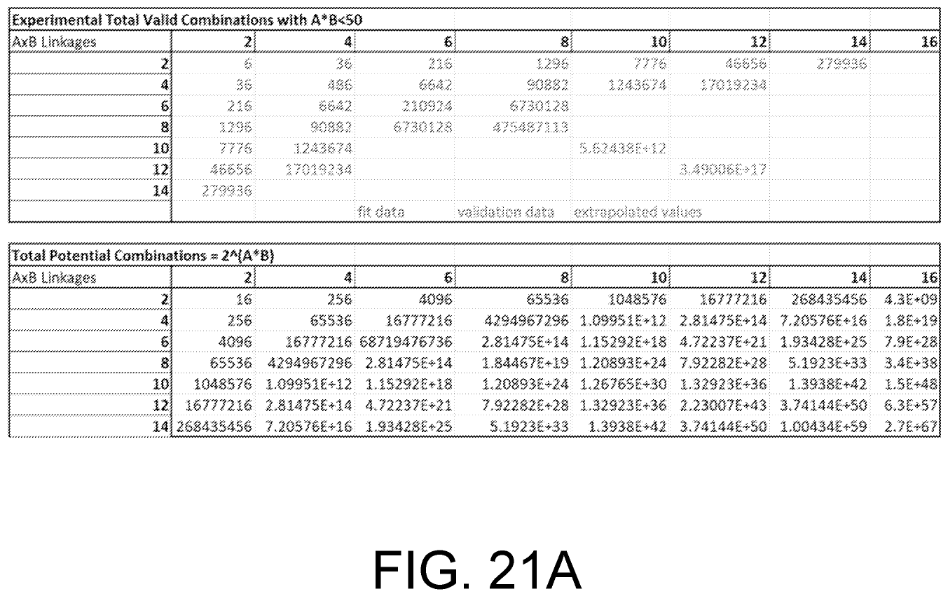

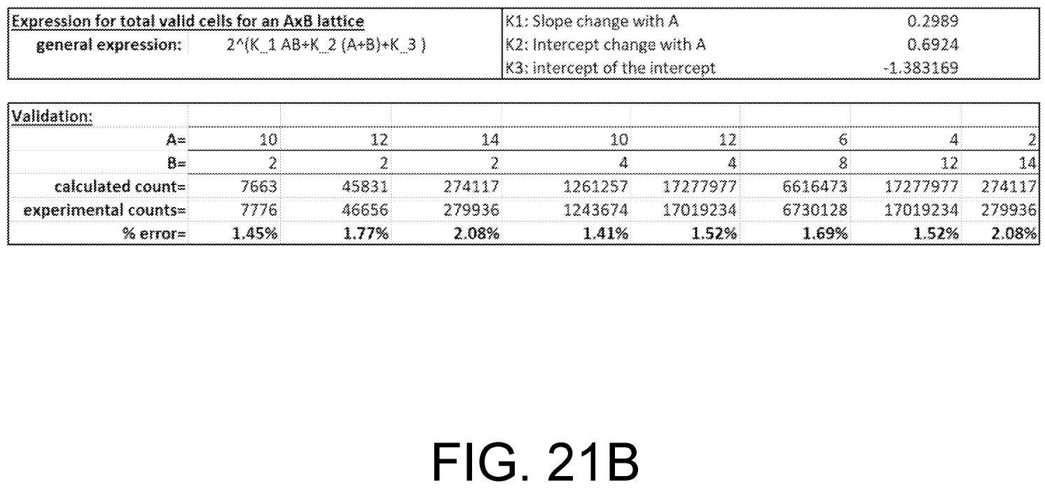

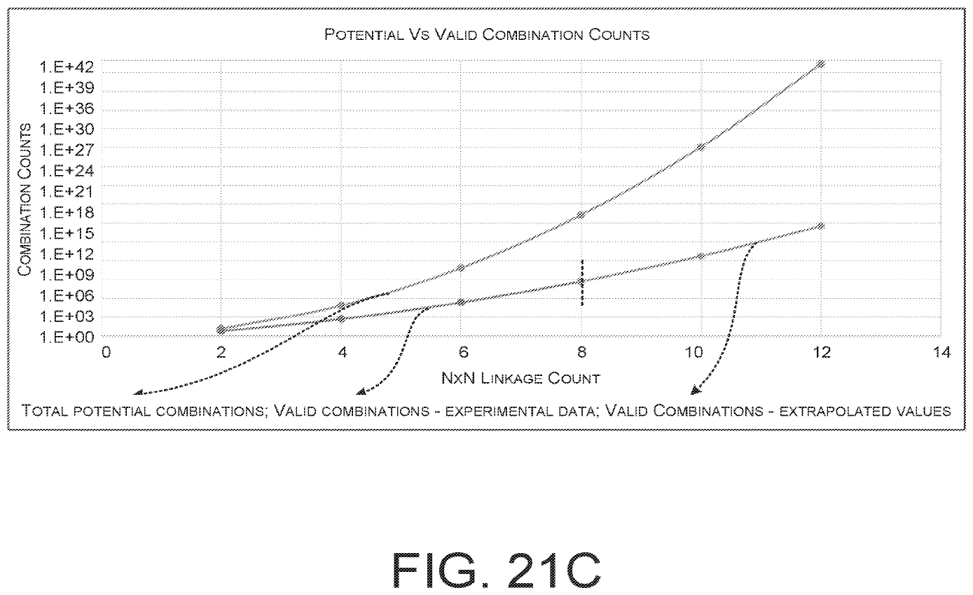

In this Example 8, combinatorial design space is discussed. FIG. 21A, FIG. 21B, and FIG. 21C illustrate a combination space for total joint combinations and valid joint combinations. As unit cell count increases, total joint combinations expand far more rapidly than valid cell count. Tables shown in FIG. 21A and FIG. 21B display the valid combination count and the total potential combination count in relation to A×B linkage number lattice dimensions.

To derive an expression for the total number of valid leaf nodes, the researchers generated and tested every candidate combination of an A×B linkage array up to A*B<50 and A, B<16. This data created a symmetric matrix with 25 total points (referring to FIG. 21A, FIG. 21B, and FIG. 21C). Of these combinations, the researchers selected 17 points to act as fit data, and 8 points to act as validation data. By taking the log₂ of the fit data for valid configurations, the researchers were able to generate the best fit lines for A=2,4,6,8 as B increased, with R²>0.99998. The slope and intercepts of these four lines also fit a linear relationship as the A value increased, such that R²>0.99999. This logarithmic relationship and the two linear equations combined to create a single general equation to describe the valid combination space as A and B varied. The number of total valid combinations=2^{k}^{₁}^{AB+k}^{₂}^{(A+B)+k}^{₃} with the three constants, k1=0.2989, k2=0.6924, k3=−1.3831, obtained through the linear fits. The researchers tested this general equation using our validation data and achieved error<2.1% for all points (referring to FIG. 21A, FIG. 21B, and FIG. 21C).

### Example 9

In this Example 9, flat-backed lattice configurations are discussed. The researchers created an algorithm to generate a valid lattice configuration for arbitrary edge conditions on one side of the lattice and a flat edge on the other side. Following the same notation as the combinatorial cell assigning algorithm, the researchers represent each vertical linkage as a positive (1) or negative (0) value based on its slope. Starting with the defined profile, the researchers step through each column of the lattice, reducing the difference between the maximum and minimum horizontal offset in the column (jointmax−jointmin). To fully configure each unit cell in the lattice, the researchers perform the state designating algorithm outlined in this disclosure. For the flat back algorithm, instead of configuring cells to reduce the difference between opposite edges of the lattice, the researchers aim to reduce the average horizontal offset for each column.

### Example 10

In this Example 10, profile matching is discussed. To match a compressed reentrant honeycomb lattice to an arbitrary profile, the researchers first broke the profile into ns discrete line segments, each with a length Lp and a slope angle θp. Three factors limit the shape of profiles that the researchers can accurately approximate. First, the distance between the minimum and maximum horizontal offset must be less than the maximum horizontal displacement of the lattice (jointmax−jointmin). Second, considering that θp=0, π represents horizontal lines, the profile must be made up of line segments with slopes 0<θp<π. This means that all profiles must be approximated as functions with a single x value mapping directly to a single y value. The value of θp is further limited by the dimensions of each cell (referring to FIG. 8A, FIG. 8B, and FIG. 8C), since geometric interference will occur before the cell can be compressed completely flat. Finally, the total height of the profile must be less than the total height of the lattice structure in its compressed state. Here, the magnitude of compression can be governed either by the maximum slope |θp| or the minimum cell height required to accurately match the profile. To approximate an arbitrary profile or function, the researchers once again define the shape as a combination of positively sloped segments (1) and negatively sloped segments (0). For a lattice with A×B linkages, the researchers start by splitting a predefined profile into A segments and assigning each point an x and a y value. The researchers then determine the distance that the lattice must compress so that each link height (h) matches each profile line segment. Based on the magnitude of compression, the researchers find θp=arcsin (h) where h is segment height. To fill in the lattice edge values, the researchers start from the top and increment a horizontal displacement value. If the horizontal displacement value is greater than the current profile x value, then the researchers include a 0 in the lattice edge array. Otherwise, the researchers include a 1 in the array, repeating this process until the array is fully populated (Referring to S11 and S15 in the pseudo code in Example 19).

### Example 11

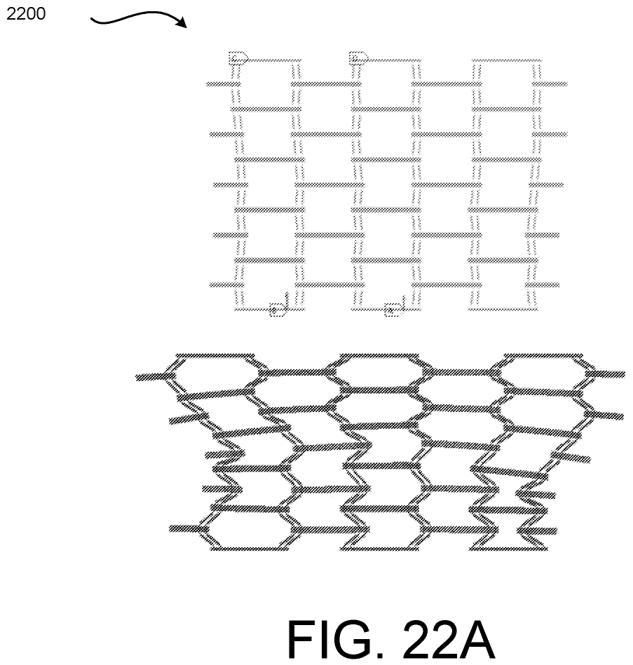

In this Example 11, simulation of large 2D profiles is discussed. FIG. 22 illustrates FEA simulation 2200 that validated the design strategy for creating predictably compressible lattice structures. The pictured structure accurately represents the compression of the physical lattice shown in FIG. 16D.

The researchers performed simulations of the 2D profiles using Ansys static structural simulation tools. The researchers set mesh size for the simulation to be a resolution of 7 and enabled large deformations. For structural constraints, the researchers grounded the base of one cell at the bottom of each lattice and constrained the remaining bottom edge points, allowing deformation in only the x direction. The researchers assigned negative 14.7 mm/cell z displacement at the edge of each top cell. All cell movement remained free in the x direction, except for one point on the top surface that the researchers fixed, grounding the displacement.

The researchers simulated the lattice (referring to FIG. 16D) to validate the lattice design strategies. To create a CAD lattice design, the researchers manually combined a series of positively and negatively sloped joints in fusion 360. Rather than apply individual biasing forces at each joint, the researchers assigned an initial slope offset of 5 degrees to each vertical linkage to establish the buckling direction. The researchers simulated the global compression of the structure using the finite element approach described above (referring to FIG. S7B). To generate complex profiles such as those shown in FIG. 17, the researchers manually created profiles and then generated the corresponding lattice using the profile generation algorithm.

### Example 12

In this Example 12, lattice selection is discussed. To select a lattice with desired shape changing capabilities, three requirements must be met. First, the state space of the lattice must make up a star graph with all leaf nodes being accessible from a single central node. Second, the star graph configuration must have enough valid states to enable arbitrary shape change. For example, lattices such as the double arrowhead or chiral structures support the star graph configuration but have small state spaces that are limited by geometric constraints. To ensure that the number of valid states grows rapidly as cell count increases, adjacent cells must be independently programmable. Finally, individual cells of the structure must be capable of switching between discrete Poisson's ratios. For both the reentrant honeycomb and the double arrowhead structures, the Poisson's ratio can be set to either a positive or a negative value based on the interior joint angle of θ. This property allows the width of compressed cells to be programmatically set, enabling shape change within the lattice.

Two common auxetic structures that can be dynamically switched between discrete positive and negative Poisson's ratios are the reentrant honeycomb [1]-[5] (referring to FIG. 8B) and the double arrowhead lattice [1], [6]-[8] (referring to FIG. 8A). As shown in FIG. S1, the transition between positive and negative compressive trajectories occurs when each joint has an angle of θ=π/2. As a result, any cell with an initial angle θ>π/2 will expand laterally as the structure is compressed, and any cell with an initial angle θ<π/2 will contract laterally as the structure is compressed. The rotating squares structure [9] (referring to FIG. 8C) is an example of a geometry that remains auxetic throughout the entire trajectory of θ. Regardless of the initial bias of the expanded state, the structure will continue to compress laterally as it is compressed axially. This makes the rotating square structure a poor candidate for generating edge profiles.

To select a successful structure, the researchers represent a complete lattice as a combination of mirrors and translations, with dashed lines denoting mirrors in FIG. 8A, FIG. 8B, and FIG. 8C, and vectors l₁ and l₂ denoting translations. As θ develops between the angles θ to π, the unit cell transforms continuously, scaling such that system matrix G̅=[₀^{g}^{₁₁}^{(θ)} _{g}_{₂₂}_{(θ)}⁰]. The instantaneous transformation of the system can be described as \overline{\dot{L}}(θ)=G̅(θ)·L̅(θ), where matrix L̅=[l1, l2] defines the tiling of the unit cell and \overline{\dot{L}}(θ) is the instantaneous transformation of the tiling [9]. When the det (G̅)=0, the researchers can check the Tr(G̅) to determine the trajectory of the system. If Tr(G̅)=0, then the system will remain either auxetic or non-auxetic throughout the range of θ. If Tr(G̅)≠0, then the system will switch from auxetic to non-auxetic at the point when det (G̅)=0 [9]. Both the double arrowhead structure and the inverse honeycomb structure can be shown to exhibit this behavior. Star auxetic structures [10] also show this behavior but are not included within the scope of this paper.

### Example 13

In this Example 13, star graph representations of lattice configurations are discussed. Lattice structures such as rotating squares (Chiral structures) and double arrowhead lattice, can be represented as 2D kinematic linkages of rigid bars, transforming based on the angle θ. If the value of θ is maintained as equal for every unit cell in the lattice, then the structure has a single trajectory path, and the state depends on one value of θ between θmin and θmax. However, if the value of θ varies independently between separate unit cells, then the full lattice can transition between a larger set of different states. For such structures, a single state exists when θ=π/2, such that every other state can be accessed by setting every individual unit cell angle to be θ>π/2 or θ<π/2. Once each initial value of θ has been set such that θ≠π/2, the compressive trajectory of the structure is fully defined, and the structure will continue to transition along a set path. This behavior can be represented with a star graph Sn of order n [11]. Here the researchers can consider the internal node of the star graph to be the point at which θ=π/2 for each cell. Every other accessible state of the lattice makes up the leaves of the star graph.

The 4-bar chiral lattice [1] is one such geometry that can be described with this star graph data structure. Here, the current state of the structure can be defined by a combination of zero, clockwise, or counterclockwise center rotations and linkage rotations for each unit cell. As the cell count for the lattice increases, the chiral star graph has an exponentially increasing number of valid accessible leaves. However, each unit cell can only take on negative or zero Poisson's ratios and no positive Poisson's ratio options exist. This limits the shape changing capabilities of the lattice, requiring external shearing forces to generate horizontal deformation. Having no positive Poisson's ratio cell deformation also limits the ability of the lattice to vary cell type in multiple directions.

For the double arrowhead lattice, state configurations are defined by the values of each angle θ for every unit cell joint. For a lattice with A×B joints, there are 2^{A*B} potential joint combinations, but the number of valid configurations is greatly limited by geometric restrictions. Having no shearing configuration, unit cell type can be adjusted in stripes, but like the chiral lattice, local cell changes in two directions are limited. To maintain valid physical linkage configurations in the lattice, all cells within a row must maintain a constant value of θ. This means that cell type in the lattice can only be adjusted column by column, reducing the number of total valid combinations from 2^{A*B} to 2^{B}. With these physical restrictions, the researchers can adjust the effective global Poisson's ratio of the double arrowhead lattice, but the researchers cannot generate spatially varying Poisson's ratios or complex profiles. It should be noted, these restrictions exist with the assumption that the lattice structure remains in the 2D plane. Out of plane deformations may open an even broader design space for deforming lattice structures with star graph representations.

Compared to the chiral and double arrowhead lattice structures, the reentrant honeycomb has a much larger valid combinations space. For a 3×3 grid of reentrant honeycomb cells, there exists a total of 6561 valid states that meet all geometric requirements. The researchers determined the total number of valid reentrant honeycomb states using the validity check algorithm outline in this disclosure, and S12 in the pseudo code in Example 19. To select specific state changes, the researchers use the profile approximation algorithm and the cell assigning algorithms detailed in this disclosure and S13, S14 in the pseudo code in Example 19.

### Example 14

In this Example 14, the required number of programming elements are discussed. A single cell of the inverse honeycomb consists of four vertical linkages and two horizontal linkages. As the researchers compress a lattice, each vertical linkage will flex left or right, making each cell have 4 degrees of freedom. As the researchers expand the cell count to an N×M cell lattice, with N rows and M columns, every cell in the first column (M=1) increments the total linkage count by 4. For multiple columns (M>1), each adjacent cell shares 2 vertical linkages. Accordingly, for every cell in the preceding columns, the total vertical linkage count is incremented by 2. As a result, a lattice has a total linkage count of 2N*(M+1). The biasing mechanisms in the system each constrain the movement of two linkages at a time. Hence, each linkage in the system can be fully constrained by placing actuators at every other element, so the total number of actuators for an N×M cell system is N*(M+1).

### Example 15

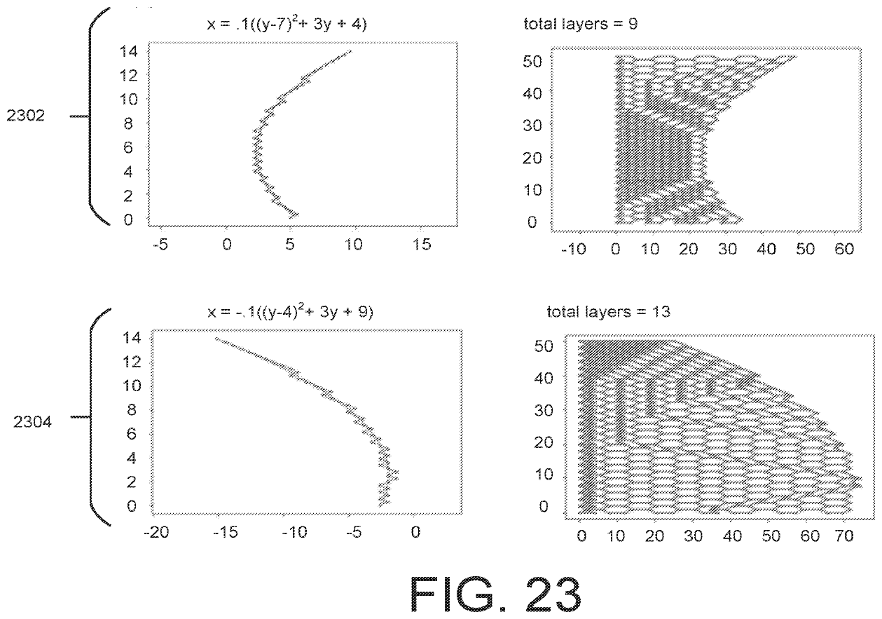

In this Example 15, lattice profile generation and curve fitting are discussed. FIG. 23 illustrates function approximation and lattice representation according to implementations of this disclosure. Referring to FIG. 23, 2302 shows an example of concave using the profile approximation algorithm (referring to S15 in the pseudo code in Example 19) and the lattice generation algorithm (referring to S14 in the pseudo code in Example 19). 2304 shows an example of convex function estimation using the profile approximation algorithm (referring to S15 in the pseudo code in Example 19) and the lattice generation algorithm (referring to S14 in the pseudo code in Example 19).

The researchers approximated arbitrary functions with corresponding lattice configurations using the algorithms outlined in S14 in the pseudo code in Example 19. The researchers did this by first generating evenly spaced x,y points for the desired function. Second, the researchers fit the closest possible mapping for a lattice edge (referring to S13 in the pseudo code in Example 19) made up of uniform positive and negatively sloped line segments. Finally, the researchers used the cell generation algorithm (referring to S14 in the pseudo code in Example 19) to fill in a valid lattice configuration that will map from the function profile to a flat edge (1,0,1,0,1,0 . . . ). Two examples of function approximation can be seen in FIG. 23.

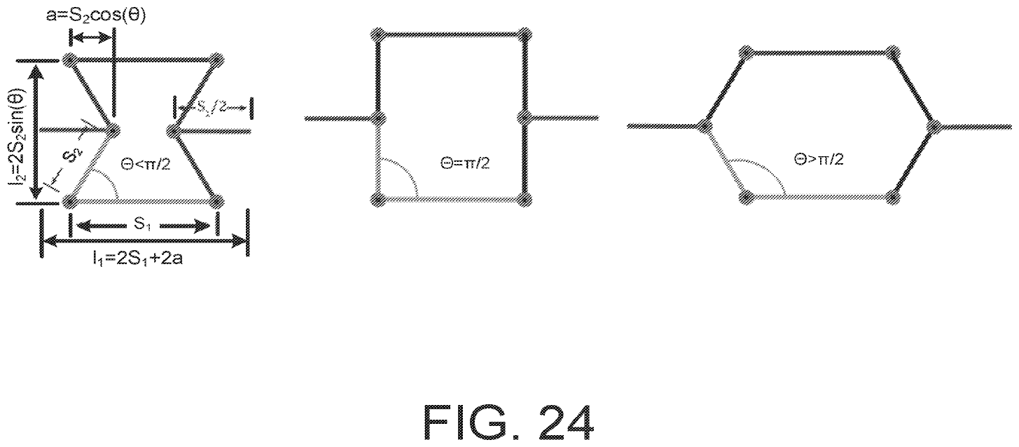

FIG. 24 illustrates transition modes for honeycomb unit cells according to implementations of this disclosure. The researchers define honeycomb unit cells based on dimensions S₁ and S₂. The tiling vectors l₁ and l₂ depend on the dimensions and the angle θ. Maximum horizontal displacement and maximum possible slope of a lattice become important parameters when selecting the geometry of a lattice and approximating profiles. As shown in FIG. 24, each cell's geometry can be described with horizontal link length S₁ and vertical link length S₂. The final compressed height of a cell can be expressed as l₂=2S₂−c such that c is the magnitude of the cell's vertical compression and S₂ is the vertical link length. If the initial angle of a joint is constrained to θ<π2, the compressed joint angle

$$θ = arc sin ( \frac{{l}_{2}}{2 {S}_{1}} )$$

throughout the trajectory of the cell's compression. If the initial angle θ>π/2, the compressed angle

$$θ = π - arc sin ( \frac{{l}_{2}}{2 {S}_{1}} )$$

as the cell compresses. θ can then be used to find the horizontal displacement of each linkage, a=S₂ cos (θ). The total effective width of a compressed cell is l₁=2S₁+2a.

### Example 16

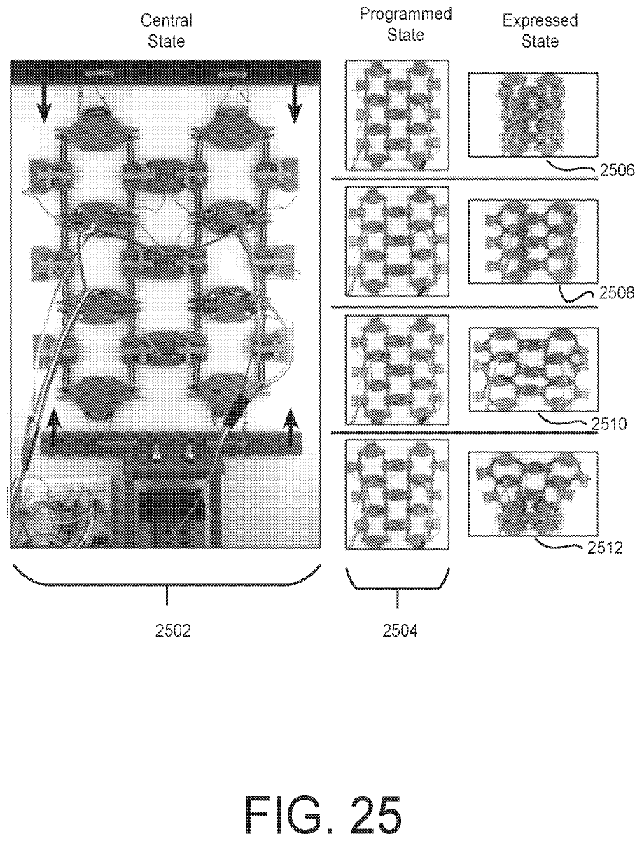

In this Example 16, electrically actuated structures are discussed. FIG. 25 illustrates robotically switching lattice according to implementations of this disclosure. A stepper motor applied a global compressive force to the structure and individual joints programmed using an array of linear servo motors. 2002 shows that the lattice is in a central state. 2504 shows that the lattice is programmed to buckle into multiple different configurations. 2506 shows that the lattice has a global negative Poisson's ratio. 2508 shows that the lattice has a global zero Poisson's ratio. 2510 shows that the lattice has a global positive Poisson's ratio. 2512 shows that the lattice has a vertical transition in Poisson's ratio from positive to negative.

The researchers fabricated a planar honeycomb structure with small Mgaxyff analog micro linear servo motors to bias the system. The setup included 12 small linear servo motors driven by chained PCBs and controlled by an Arduino. Each PCB consisted of a PCA9685 16 channel servo driver, along with a 4 RGBLED lights and 4 solder jumpers to assign an address for each unit. The researchers fabricated compliant joints from 3D printed TPU filament and all other lattice components from PLA. To program each joint configuration, servo motors slid small plates with cantilevered posts to push each joint to π/2>θ or θ<π/2 (referring to S10 in the pseudo code in Example 19). The researchers actuated global transformations in the structure using a single Nema 17 stepper motor connected to a ball screw linear actuator.

To demonstrate feasibility, the researchers programmed the system to transition between four preset states. FIG. 24 shows the lattice states as it transitions between the central node and a net positive Poisson's ratio state, a net negative Poisson's ratio state, and a net zero Poisson's ratio state. The structure performed these transformations by first, moving all servo motors to a neutral and unbiased state. Second, using the stepper motor to extend the lattice to its maximum length (central node). Third, actuating all linear servos to bias all joints in the lattice. And finally, using the stepper motor to compress the structure to the new configuration.

### Example 17

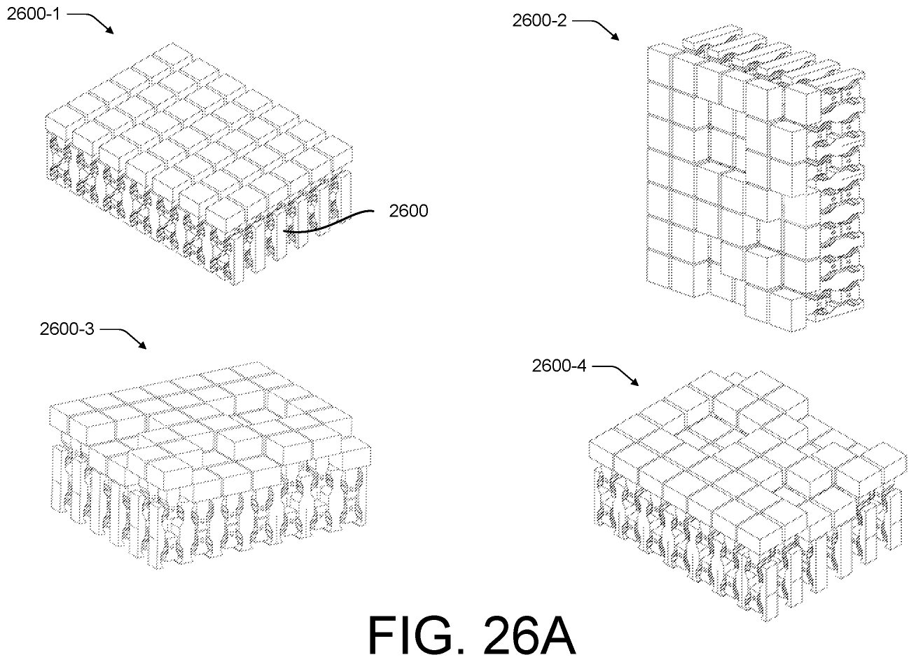

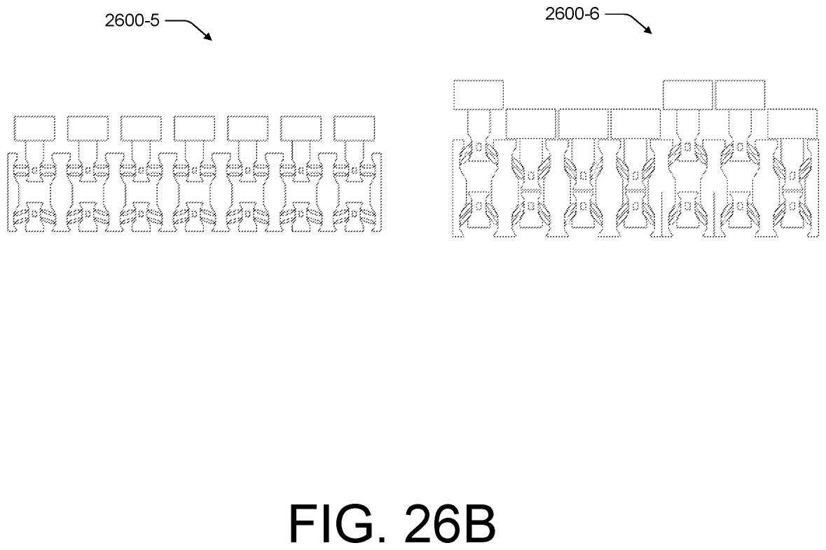

In this Example 17, another example reprogrammable system 2600 is discussed. FIG. 26A illustrates various perspective views of the reprogrammable system 2600 according to implementations of this disclosure. Referring to FIG. 26A, 2600-1 shows a first perspective view of the reprogrammable system 2600. 2600-2 shows a second perspective view of the reprogrammable system 2600. 2600-3 shows a third perspective view of the reprogrammable system 2600. 2600-4 shows a fourth view of the reprogrammable system 2600. FIG. 26B illustrates various side views of the reprogrammable system 2600 according to implementations of this disclosure. Referring to FIG. 26B, 2600-5 shows a first side view of the reprogrammable system 2600. 2600-6 shows a second side view of the reprogrammable system 2600. The reprogrammable system 2600 may have similar configurations and functions as the reprogrammable system 100. In implementations, the reprogrammable system 2600 has only one row of unit cells in each reprogrammable layer. The reprogrammable system 2600 can be controlled using techniques discussed throughout this disclosure and achieve similar technical effects as the reprogrammable system 100.

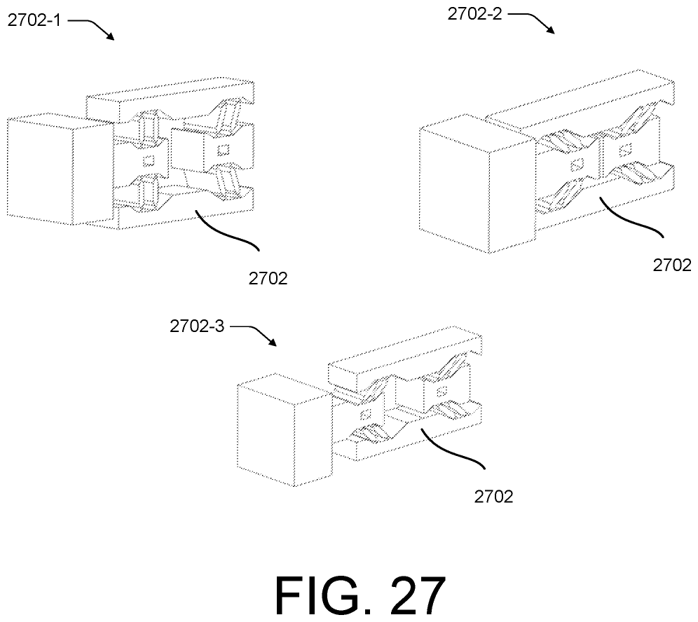

FIG. 27 illustrates various views of an example individual unit cell 2702 in the reprogrammable system 2700 according to implementations of this disclosure. Referring to FIG. 27, 2702-1 shows a first view of the individual unit cell 2702, where the individual unit cell 2702 is in an uncompressed state. 2702-2 shows a second view of the individual unit cell 2702, where the individual unit cell 2702 is in an auxetic state. 2702-3 shows a third view of the individual unit cell 2702, where the individual unit cell 2702 is in a zero Poisson's ratio state.

### Example 18

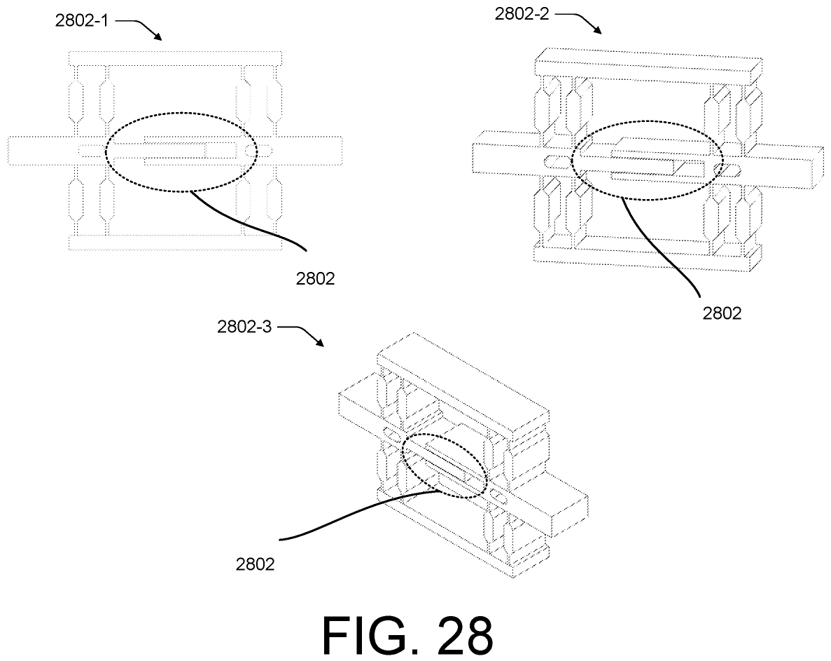

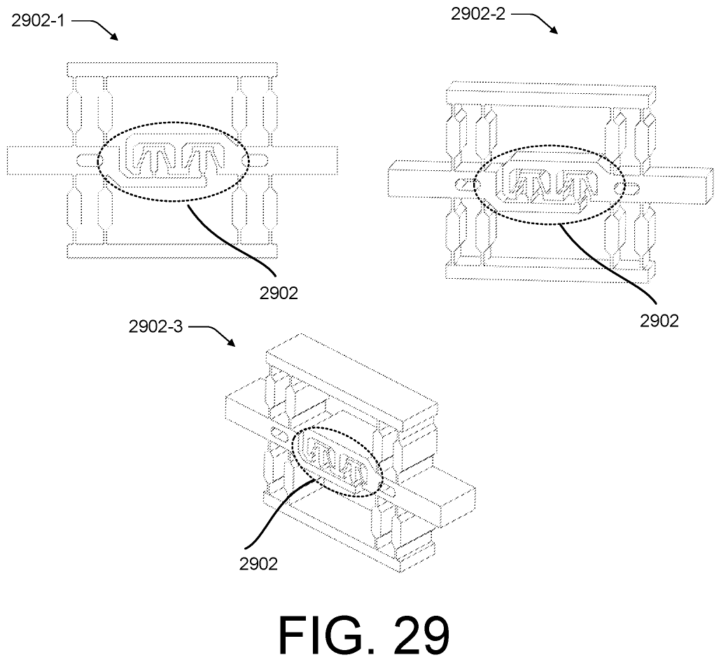

In this Example 18, collinear mechanisms are discussed. FIG. 28 illustrates various views of an example individual unit cell with an example collinear mechanism according to implementations of this disclosure. Referring to FIG. 28, 2802-1 shows a first view of the example individual unit cell with the example collinear mechanism 2802. 2802-2 shows a second view of the example individual unit cell with the example collinear mechanism 2802. 2802-3 shows a third view of the example individual unit cell with the example collinear mechanism 2802. FIG. 29 illustrates various views of an example individual unit cell with another example collinear mechanism 2902 according to implementations of this disclosure. Referring to FIG. 29, 2902-1 shows a first view of the example individual unit cell with the example collinear mechanism 2902. 2902-2 shows a second view of the example individual unit cell with the example collinear mechanism 2902. 2902-3 shows a third view of the example individual unit cell with the example collinear mechanism 2902.

To ensure that the state-changing algorithm remains valid, all horizontal beams/elements must remain parallel over the structure's trajectory. Under some loading conditions, cells in the shear state may compress unevenly, breaking this parallel beam constraint. To solve this problem, one of several additional strategies can be introduced to maintain collinearity. For the simplest solution, the researcher can fully the structure until interference between the top and the bottom of each cell forces the beams/elements to become parallel. This strategy works if the researchers are only considering the endpoint of the shape's trajectory. However, throughout the entire transformation of the structure, the parallel constraint may not be ensured, at which point uneven compression could create inaccuracy in the shape. As an alternate solution, the research can add additional geometric components to ensure collinearity between the horizontal beams/elements. The researchers offer two straight-line strategies that can be included in the unit cells. First, the researchers can add a groove and slot (2802) that reaches between the two beams/elements. The groove slides back and forth in the slot, allowing expansion and contraction but no rotation. Second, the researchers can add a Double-Roberts Mechanism (2902) between the two beams/elements. A Robert's mechanism is a straight-line mechanism used to fix the motion of a single point to a linear path. By adding two Robert's mechanisms side by side, the researchers can enforce collinearity between the two connected beams/elements. Both these additions will maintain the horizontal beam condition throughout the entire trajectory of the structure's compression. This ensures that compression of the structure will induce accurate shape changes along the edge of the lattice.

It should be understood that the collinear mechanisms (2802 and 2902) discussed here are examples. Other mechanisms that maintain collinearity between elements of unit cells can be used, and this disclosure is not limited thereto.

### Example 19

In this Example 19, the pseudo code for implementing processes and operations according to this disclosure is presented. It should be understood that the pseudo code presented here is an example, and this disclosure is not limited thereto.

### S12. Pseudo Code for Validity Check:

‘Set x values for every joint in the lattice. Check that x values match linkage constraints’

```
INIT top_left_xval to 0
FOR top_cells in lattice_width
  SET xval to left_xval plus width
  IF top_cell=even
    ADD left_a_values to xval
For all_cells in column
  For all columns
    SET xval to above_xval plus above_a_val
For all_cells in column
  For all columns
    IF column and row number = odd
      IF xval not = left_xval plus width
        Lattice FAILS
    IF column and row number = even
      IF xval not = left_xval plus width
        Lattice FAILS
    ELSE Lattice VALID
```

### S13. Pseudo Code for Solving Arbitrary Profile to Flat Back:

‘Solve joint values for a lattice starting with an arbitrary profile (1,1,0,1,0,0,0 . . . ) and ending with a flat back (1,0,1,0,1,0 . . . )’

```
INIT initial_profile
WHILE not flat_back
  Add 1 to layer_count
  ‘Define horizontal linkages in lattice’
  IF layer_count = even
    INIT even_horizontal_linkages
  ELSE
    INIT odd_horizontal_linkages
  INIT new_profile
  FOR linkages in initial_profile
    INIT profile_mid_xvalue
    IF linkage_index = horizontal_linkage
      ‘If 2 links have the same value in between horizontal linkages
      Then the cell is a shear element and fully defined’
      IF linkage_value=next_linkage_value
        SET new_profile_link to linkage_value
        SET next_new_profile_link to next_linkage_value
    ELSE
      ‘Make x values stabilize towards a center value to flatten profile’
      IF linkage_xval>profile_mid_xvalue
        SET new_profile_link to negative_slope
        SET next_new_profile_link to positive_slope
        ‘Profile with positive Poisson's ratio’
      ELSE
        SET new_profile_link to positive_slope
        SET next_new_profile_link to negative_slope
      ‘Profile with negative Poisson's ratio’
  SET initial_profile to new_profile
  Call: validity_check
  Call: flat_back_check
RETURN full_lattice
```

### S14. Pseudo Code for Profile Approximation:

‘Take arbitrary function or profile and generate approximation in terms of positive and negative sloped line segments.’

```
INIT ideal_profile
INIT profile_match
‘Slice the ideal profile into x and y points’
FOR number_of_slices in ideal_profile
  INIT profile_x_values
  INIT profile_y_values
‘Determine magnitude of lattice compression’
Call: find_max_slope
Call: find_total_compression_distance
‘Iterate along the profile assigning positive or negative slopes to the profile
approximation’
INIT current_x_value to 0
FOR cells in number of slices
  IF profile_x_value>current_x_value
    ADD positive_value to profile_match
  ELSE
    ADD negative_value to profile_match
RETURN profile_match
```

As will be understood by one of ordinary skill in the art, each embodiment disclosed herein can comprise, consist essentially of or consist of its particular stated element, step, ingredient or component. Thus, the terms “include” or “including” should be interpreted to recite: “comprise, consist of, or consist essentially of.” The transition term “comprise” or “comprises” means has, but is not limited to, and allows for the inclusion of unspecified elements, steps, ingredients, or components, even in major amounts. The transitional phrase “consisting of” excludes any element, step, ingredient, or component not specified. The transition phrase “consisting essentially of” limits the scope of the embodiment to the specified elements, steps, ingredients or components and to those that do not materially affect the embodiment.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it is individually recited herein. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments of this invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

It is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

The particulars shown herein are by way of example and for purposes of illustrative discussion of the preferred embodiments of the present invention only and are presented in the cause of providing what is believed to be the most useful and readily understood description of the principles and conceptual aspects of various embodiments of the invention. In this regard, no attempt is made to show structural details of the invention in more detail than is necessary for the fundamental understanding of the invention, the description taken with the drawings and/or examples making apparent to those skilled in the art how the several forms of the invention may be embodied in practice.

Further, the techniques and operations discussed herein with reference to FIGS. 1A-29 may be implemented in hardware, software, or a combination thereof. In the context of software, the described operations represent computer-executable instructions stored on one or more computer-readable storage media that, when executed by one or more hardware processors, perform the recited operations. Generally, computer-executable instructions include routines, programs, objects, components, data structures, and the like that perform particular functions or implement particular abstract data types. Those having ordinary skills in the art will readily recognize that certain steps or operations illustrated in the figures above may be eliminated, combined, or performed in an alternate order. Any steps or operations may be performed serially or in parallel (unless the context requires one or the other). Furthermore, the order in which the operations are described is not intended to be construed as a limitation.

Embodiments may be provided as a software program or computer program product including a non-transitory computer-readable storage medium having stored thereon instructions (in compressed or uncompressed form) that may be used to program a computer (or other electronic device) to perform processes or methods described herein. The computer-readable storage medium may be one or more of an electronic storage medium, a magnetic storage medium, an optical storage medium, a quantum storage medium, and so forth. For example, the computer-readable storage media may include, but is not limited to, hard drives, floppy diskettes, optical disks, read-only memories (ROMs), random access memories (RAMs), erasable programmable ROMs (EPROMs), electrically erasable programmable ROMs (EEPROMs), flash memory, magnetic or optical cards, solid-state memory devices, or other types of physical media suitable for storing electronic instructions. Further, embodiments may also be provided as a computer program product including a transitory machine-readable signal (in compressed or uncompressed form). Examples of machine-readable signals, whether modulated using a carrier or unmodulated, include, but are not limited to, signals that a computer system or machine hosting or running a computer program can be configured to access, including signals transferred by one or more networks. For example, the transitory machine-readable signal may comprise transmission of software by the Internet.

Separate instances of these programs can be executed on or distributed across any number of separate computer systems. Thus, although certain steps have been described as being performed by certain devices, software programs, processes, or entities, this need not be the case, and a variety of alternative implementations will be understood by those having ordinary skills in the art.

Additionally, those having ordinary skills in the art readily recognize that the techniques described above can be utilized in a variety of devices, environments, and situations. Although the subject matter has been described in language specific to structural features or methodological acts, it is to be understood that the subject matter defined in the appended claims is not necessarily limited to the specific features or acts described. Rather, the specific features and acts are disclosed as exemplary forms of implementing the claims.

Those of ordinary skill in the art will recognize in light of the present disclosure that many changes can be made to the specific embodiments disclosed herein and still obtain a like or similar result without departing from the spirit and scope of the disclosure.

### REFERENCES

[1]. Panetta, D., Buresch, K. & Hanlon, R. T. Dynamic masquerade with morphing three-dimensional skin in cuttlefish. Biology Letters 13, 20170070 (2017).
[2]. Phenotypic plasticity raises questions for taxonomically important traits: a remarkable new Andean rainfrog (Pristimantis) with the ability to change skin texture|Zoological Journal of the Linnean Society|Oxford Academic. https://academic.oup.com/zoolinnean/article/173/4/913/2449834?login=true.
[3]. Oliver, K., Seddon, A. & Trask, R. S. Morphing in nature and beyond: a review of natural and synthetic shape-changing materials and mechanisms. J Mater Sci 51, 10663-10689 (2016).
[4]. Water-induced finger wrinkles improve handling of wet objects|Biology Letters. https://royalsocietypublishing.org/doi/full/10.1098/rsbl.2012.0999.
[5]. Follmer, S., Leithinger, D., Olwal, A., Hogge, A. & Ishii, H. inFORM: dynamic physical affordances and constraints through shape and object actuation. in Proceedings of the 26th annual ACM symposium on User interface software and technology 417-426 (ACM, 2013). doi:10.1145/2501988.2502032.
[6]. Grand Challenges in Shape-Changing Interface Research I Proceedings of the 2018 CHI Conference on Human Factors in Computing Systems. https://dl.acm.org/doi/abs/10.1145/3173574.3173873.
[7]. Liu, K., Hacker, F. & Daraio, C. Robotic surfaces with reversible, spatiotemporal control for shape morphing and object manipulation. Science Robotics 6, (2021).
[8]. Leithinger, D. et al. Sublimate: state-changing virtual and physical rendering to augment interaction with shape displays. in Proceedings of the SIGCHI Conference on Human Factors in Computing Systems 1441-1450 (Association for Computing Machinery, 2013). doi:10.1145/2470654.2466191.
[9]. Zareei, A., Deng, B. & Bertoldi, K. Harnessing transition waves to realize deployable structures. Proceedings of the National Academy of Sciences 117, 4015-4020 (2020).
[10]. Coulais, C., Teomy, E., de Reus, K., Shokef, Y. & van Hecke, M. Combinatorial design of textured mechanical metamaterials. Nature 535, 529-532 (2016).
[11]. Mukhopadhyay, T. et al. Programmable stiffness and shape modulation in origami materials: Emergence of a distant actuation feature. Applied Materials Today 19, 100537 (2020).
[12]. van Manen, T., Janbaz, S. & Zadpoor, A. A. Programming the shapeshifting of flat soft matter. Materials Today 21, 144-163 (2018).
[13]. Mirzaali, M. J. et al. Rational design of soft mechanical metamaterials: Independent tailoring of elastic properties with randomness. Applied Physics Letters 111, 051903 (2017).
[14]. Mirzaali, M. J., Janbaz, S., Strano, M., Vergani, L. & Zadpoor, A. A. Shape-matching soft mechanical metamaterials. Scientific reports 8, 1-7 (2018). FIG. 4|3D Surface Expression. Stacking multiple star graph lattice structures creates reprogrammable 3D height maps. A surface height encoding corresponds to layers of programmed 2D structures. The physically encoded information is expressed by compressing the structure.
[15]. Fozdar, D. Y., Soman, P., Lee, J. W., Han, L.-H. & Chen, S. Threedimensional polymer constructs exhibiting a tunable negative Poisson's ratio. Advanced functional materials 21, 2712-2720 (2011).
[16]. Pikul, J. H. et al. Stretchable surfaces with programmable 3D texture morphing for synthetic camouflaging skins. Science 358, 210-214 (2017).
[17]. Hedayati, R., Mirzaali, M. J., Vergani, L. & Zadpoor, A. A. Action-at-adistance

metamaterials: Distributed local actuation through far-field global forces. APL Materials 6, 036101 (2018).
[18]. Chen, Y., Li, T., Scarpa, F. & Wang, L. Lattice metamaterials with mechanically tunable Poisson's ratio for vibration control. Physical Review Applied 7, 024012 (2017).
[19]. Qiao, J. X. & Chen, C. Q. Impact resistance of uniform and functionally graded auxetic double arrowhead honeycombs. International Journal of Impact Engineering 83, 47-58 (2015).
[20]. Li, D., Dong, L. & Lakes, R. S. A unit cell structure with tunable Poisson's ratio from positive to negative. Materials Letters 164, 456-459 (2016).
[21]. Wang, H., Lu, Z., Yang, Z. & Li, X. In-plane dynamic crushing behaviors of a novel auxetic honeycomb with two plateau stress regions. International Journal of Mechanical Sciences 151, 746-759 (2019).
[22]. Kadic, M., Milton, G. W., van Hecke, M. & Wegener, M. 3D metamaterials. Nature Reviews Physics 1, 198-210 (2019).
[23]. Milton, G. W. & Cherkaev, A. V. Which Elasticity Tensors are Realizable? Journal of Engineering Materials and Technology 117, 483-493 (1995).
[24]. Shim, J., Perdigou, C., Chen, E. R., Bertoldi, K. & Reis, P. M. Buckling-induced encapsulation of structured elastic shells under pressure. PNAS 109, 5978-5983 (2012).
[25]. Lipton, J. I. et al. Handedness in shearing auxetics creates rigid and compliant structures. Science 360, 632-635 (2018).
[26]. Saxena, K. K., Das, R. & Calius, E. P. Three decades of auxetics research-materials with negative Poisson's ratio: a review. Advanced Engineering Materials 18, 1847-1870 (2016).
[27]. Wang, Z. & Hu, H. Auxetic materials and their potential applications in textiles. Textile Research Journal 84, 1600-1611 (2014).
[28]. Iniguez-Rabago, A., Li, Y. & Overvelde, J. T. B. Exploring multistability in prismatic metamaterials through local actuation. Nature Communications 10, 5577 (2019).
[29]. Sadoc, J.-F. & Mosseri, R. Geometrical Frustration. (Cambridge University Press, 2006).
[30]. Hedayati, R., Güven, A. & van der Zwaag, S. 3D gradient auxetic soft mechanical metamaterials fabricated by additive manufacturing. Appl. Phys. Lett. 118, 141904 (2021).

What is claimed is:

1. A reprogrammable system, comprising:
a first side configured to be reprogrammable in at least a first direction, the first side being formed by a reprogrammable structure having one or more layers stacked in a second direction;
wherein an individual layer of the one or more layers has repeating unit cells, a first unit cell of the repeating unit cells including elements, wherein the elements are connected by connecting joints; and
wherein the first unit cell of the repeating unit cells shares at least one element and/or at least one connecting joint with a second unit cell of the repeating unit cells.

2. The reprogrammable system of claim 1, further comprising:
biasing blocks configured to bias the connecting joints, wherein an individual biasing block is configured to be inserted into an individual connecting joint to bias the individual connecting joint.

3. The reprogrammable system of claim 1, further comprising:
actuators configured to actuate the connecting joints, wherein an individual actuator is coupled to an individual connecting joint to actuate the individual connecting joint; and
a controller configured to control the actuators.

4. The reprogrammable system of claim 3, wherein the individual actuator has a servo motor.

5. The reprogrammable system of claim 1, further comprising a second side configured to be reprogrammable in a direction different from the first direction.

6. The reprogrammable system of claim 1, wherein the second direction is substantially perpendicular to the first direction.

7. The reprogrammable system of claim 1, wherein the first unit cell has at least an auxetic state and/or a non-auxetic state.

8. The reprogrammable system of claim 1, wherein the first unit cell has at least a positive state with a positive Poisson's ratio, a zero state with a zero Poisson's ratio, a negative state with a negative Poisson's ratio, and/or a shear state with the zero Poisson's ratio.

9. The reprogrammable system of claim 1, wherein the connecting joints are formed of a compliant material.

10. The reprogrammable system of claim 1, wherein the elements are formed of a noncompliant material.

11. The reprogrammable system of claim 1, further comprising a global force applying device configured to apply a global force to the reprogrammable structure.

12. The reprogrammable system of claim 11, wherein the global force has a compressive force and/or an extending force.

13. The reprogrammable system of claim 1, wherein the reprogrammable structure has an extended state and a compressed state.

14. The reprogrammable system of claim 13, wherein the reprogrammable structure is configured to be programmed when the reprogrammable structure is in the extended state.

15. The reprogrammable system of claim 13, wherein the first side is further configured to display a profile when the reprogrammable structure is in the compressed state.

16. A method for controlling the reprogrammable system of any one of claims 1-15, the method comprising:
encoding the reprogrammable structure by calculating a system matrix based on a desired profile to be displayed, wherein the system matrix has joint values for connecting joints, and wherein an individual joint value defines an angle between two elements connected by an individual connecting joint;
programming the reprogrammable structure by biasing the connecting joints based on the system matrix; and
expressing the desired profile via the first side in the first direction by applying a global force to the reprogrammable structure.

17. The method of claim 16, wherein the global force is a compressive force.

18. The method of claim 16, further comprising:
applying an extending force to the reprogrammable structure; and
reprograming the reprogrammable structure by repeating the operations of claim 17.

19. The method of claim 16, wherein applying a global force to the reprogrammable structure comprises determining a magnitude of the global force.

20. The method of claim 16, wherein the global force is in a third direction, the third direction being substantially perpendicular to the first direction and the second direction.

21. The method of claim 16, wherein the global force is between 0 Newton (N) non-inclusive and 0.7 N inclusive.

22. The method of claim 16, wherein encoding the reprogrammable structure further comprises slicing the desired profile into coordinate points.

23. The method of claim 16, wherein the desired profile comprises a binary pattern.

24. The method of claim 16, wherein biasing the connecting joints comprises controlling an individual actuator to actuate an individual connecting joint to which the individual actuator coupled, to bias the individual connecting joint.

25. The method of claim 16, wherein biasing the connecting joints comprises inserting an individual biasing block into an individual connecting joint.

26. A computer-readable storage medium storing computer-readable instructions executable by one or more processors, that when executed by the one or more processors, causes the one or more processors to perform acts for controlling the reprogrammable system of any one of claims 1-15, the acts comprising:
encoding the reprogrammable structure by calculating a system matrix based on a desired profile to be displayed, wherein the system matrix has joint values for connecting joints, and wherein an individual joint value defines an angle between two elements connected by an individual connecting joint;
programming the reprogrammable structure by biasing the connecting joints based on the system matrix; and
expressing the desired profile via the first side in the first direction by applying a global force to the reprogrammable structure.
